(19) United States
(12) Patent Application Publication
(10) Pub. No.: US 2011/0083718 A1
(43) Pub. Date: Apr. 14, 2011

(54) SOLAR PANELS FOR RECEIVING SCATTERED LIGHT

(76) Inventor: Brian D. Wichner, Otter Rock, OR (US)

(21) Appl. No.: 12/970,871

(22) Filed: Dec. 16, 2010

Related U.S. Application Data
(63) Continuation-in-part of application No. 12/506,543, filed on Jul. 21, 2009.
(60) Provisional application No. 61/084,605, filed on Jul. 29, 2008.

(51) Int. Cl. H01L 31/042

(52) U.S. Cl. 136/244

(57) ABSTRACT

The subject matter disclosed herein relates to solar panels to generate electrical energy. In particular, solar panels configured to efficiently receive scattered light are disclosed. Solar panels or other light-receiving devices may be utilized to measure or detect weather or sky conditions.

### RELATED APPLICATIONS

This application is a continuation-in-part of U.S. application Ser. No. 12/506,543 by Brian Wichner, titled “SOLAR PANELS FOR RECEIVING SCATTERED LIGHT”, filed Jul. 21, 2009, which claims benefit of and priority to U.S. Provisional Patent Application 61/084,605 by Brian Wichner, titled “SOLAR PANELS FOR RECEIVING SCATTERED LIGHT”, filed Jul. 29, 2008, both of which are incorporated in their entirety by reference herein.

### BACKGROUND

1. Field

The subject matter disclosed herein relates to solar panels to generate electrical energy. In particular, solar panels configured to efficiently receive scattered light, such as during cloudy weather, are disclosed.

2. Information

Energy generation is of paramount importance to a developed country and its society. Petroleum-based energy sources are diminishing so that alternative sources of energy are becoming increasingly important. Among such alternative energy sources, solar energy generation holds promise to be an important candidate as a primary source of energy. Solar energy may be generated by solar panels, which include semiconductor materials configured in a solar cell to generate electrical energy and arranged in an array to sum the energy generated by individual solar cells. Among at least several reasons for this promising energy source: sunlight is virtually unlimited and free, and material for producing solar energy-generating panels is relatively inexpensive. On the other side of the coin, sunlight is available in limited quantities in many regions of the globe due to prevailing weather patterns that produce cloudy skies, which block a portion of sunlight. Also, although materials for producing solar panels are relatively inexpensive, manufacturing solar panels may be relatively expensive due to processing costs. Accordingly, current limitations on the use of energy-generating solar panels include geographical location due to weather, and the deployed number of solar panels due to expense.

### BRIEF DESCRIPTION OF THE FIGURES

Non-limiting and non-exhaustive embodiments will be described with reference to the following figures, wherein like reference numerals refer to like parts throughout the various figures unless otherwise specified.

FIG. 1 is a schematic diagram illustrating light rays incident on a flat solar panel, according to an embodiment.

FIG. 2 is a schematic diagram illustrating a solar panel, according to an embodiment.

FIG. 3 is a schematic diagram illustrating scattered light rays incident on a solar panel, according to an embodiment.

FIG. 4 is a schematic diagram illustrating collimated light rays incident on a solar panel, according to an embodiment.

FIG. 5 is a schematic diagram illustrating a solar panel enabled to change shape, according to an embodiment.

FIGS. 6A and 6B are schematic diagrams illustrating solar panels in a flat configuration, according to an embodiment.

FIG. 7 is a schematic diagram illustrating an array of solar panels, according to an embodiment.

FIG. 8 is a schematic diagram illustrating that light may be received on both sides of a three-dimensional solar panel.

FIGS. 9A and 9B are perspective views showing multiple three-dimensional solar panels in a stackable configuration, according to embodiments.

FIG. 10 is a plan view showing a conical solar panel in a flattened configuration, according to an embodiment.

FIG. 11 is a side view showing a roof of a house including various types of three-dimensional solar panels, according to an embodiment.

FIGS. 12-14 show top and cross-sectional views of a process of assembling a three-dimensional solar panel, according to an embodiment.

FIGS. 15-16 show cross-sectional views of a process of mounting a three-dimensional solar panel to a surface, according to an embodiment.

FIG. 17 shows a cross-sectional view of a three-dimensional solar panel mounted to a surface, according to another embodiment.

FIG. 18 shows a cross-sectional view and detailed views of a three-dimensional solar panel mounted to a surface, according to yet another embodiment.

FIG. 19 is a perspective view showing of a three-dimensional solar, according to an embodiment.

FIG. 20 is a schematic diagram illustrating photo-voltaic cells arranged on a surface, according to an embodiment.

FIG. 21 is a perspective view showing a rotatable three-dimensional solar panel, according to an embodiment.

FIG. 22 is a perspective view showing a rotatable three-dimensional solar panel, according to another embodiment.

FIG. 23 is a block diagram of components to operate a rotatable three-dimensional solar panel, according to an embodiment.

FIG. 24 is a flow diagram of a process to operate a rotatable three-dimensional solar panel, according to an embodiment.

FIG. 25 is a side view showing a rotatable photo-voltaic device, according to an embodiment.

FIGS. 26A, and 26B are front and side views showing rotatable photo-voltaic devices, according to embodiments.

FIGS. 27A-27D show example solar signals as a function of time, according to embodiments.

FIG. 28 is a top view showing a rotatable photo-voltaic device, according to an embodiment.

FIG. 29 is a block diagram of components to operate a rotatable photo-voltaic device, according to another embodiment.

FIG. 30 is a flow diagram of a process to operate a rotatable photo-voltaic device, according to another embodiment.

FIG. 31 is a perspective view showing a shape-changing three-dimensional solar panel, according to an embodiment.

FIG. 32 is a side view showing a shape-changing three-dimensional solar panel, according to an embodiment.

FIG. 33 is a perspective view showing a shape-changing three-dimensional solar panel, according to another embodiment.

FIG. 34 is a side view showing a shape-changing three-dimensional solar panel, according to another embodiment.

FIG. 35 is a perspective view showing a shape-changing three-dimensional solar panel, according to yet another embodiment.

FIGS. 36A and 36B are side views showing a shape-changing three-dimensional solar panel, according to yet another embodiment.

FIG. 37 is a perspective view showing a shape-changing three-dimensional solar panel, according to still another embodiment.

FIG. 38 is a perspective view showing a shape-changing three-dimensional solar panel, according to still another embodiment.

FIG. 39 is a side view showing geometry of solar cells on a surface, according to an embodiment.

FIGS. 40 and 41 are side views showing a shape-changing three-dimensional solar panel, according to embodiments.

FIG. 42 is a flow diagram of a process to operate a shape-changing three-dimensional solar panel, according to another embodiment.

FIGS. 43 and 44 are perspective views showing three-dimensional solar panels, according to embodiments.

FIGS. 45 and 46 are side views showing a three-dimensional solar panel, according to embodiments.

FIG. 47 is a perspective view showing a three-dimensional solar panel, according to still another embodiment.

FIG. 48 is a perspective view of a solar panel bank comprising a plurality of solar panels, according to an embodiment.

FIGS. 49 and 50 are perspective views showing multiple three-dimensional solar panels arranged in arrays, according to an embodiment.

### DETAILED DESCRIPTION

In the following detailed description, numerous specific details are set forth to provide a thorough understanding of claimed subject matter. However, it will be understood by those skilled in the art that claimed subject matter may be practiced without these specific details. In other instances, well-known methods, procedures, components, and/or circuits have not been described in detail so as not to obscure claimed subject matter.

Cloudy skies are often considered to produce less solar radiation than sunny skies. But such a simple comparison may be misleading. For example, cloudy skies may produce more solar radiation in an area that would have been a shadow if the skies were sunny. In other words, more solar radiation may reach such shadow areas via scattered sunlight from clouds. Without clouds, there may be no sunlight scattering to reach the shadow area—solar radiation may only reach areas and/or surfaces that are in direct line-of-sight of the sun during sunny weather.

In an embodiment, a solar panel, which may comprise one or more individual solar panels, may be configured in a three-dimensional shape to increase its overall surface area, while keeping its footprint area, that is, the coverage area on the earth surface or a rooftop for example, constant. Though surface area may be so increased, geometrical positioning of surfaces of such a three-dimensional shape may geometrically hinder sunlight from reaching these surfaces. However, scattered sunlight may not be so hindered since such sunlight may arrive from substantially all skyward directions, whereas non-scattered sunlight may come from one direction, the sun. Cloudy skies produce such scattered sunlight.

Particular embodiments herein describe three-dimensional solar panels including pyramidal shapes, but claimed subject matter is not so limited, since any three-dimensional solar panel may provide advantages of increased surface area while keeping a fixed footprint, as described above. Herein, the term solar panels refers to a panel in a macroscopic sense, e.g., a panel that may be placed on a rooftop as suggested above, for example.

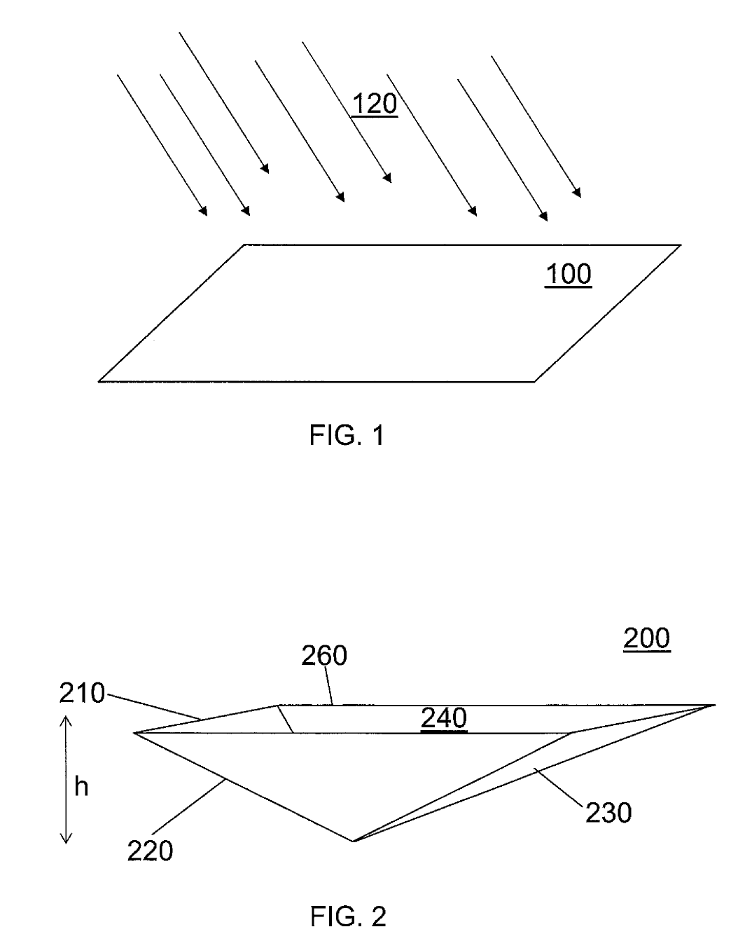

FIG. 1 is a schematic diagram illustrating light rays incident on a flat solar panel, according to an embodiment. During sunny weather, e.g., no clouds, light 120 from the sun may travel directly to a solar panel 100. A solar panel may change its angle so that sun light is incident perpendicular to the surface of the solar panel to increase solar gain efficiency.

FIG. 2 is a schematic diagram illustrating a solar panel 200, according to an embodiment. Solar panel 200 may have substantially an inverted four-sided pyramidal shape made from four individual solar panels 210, 220, 230, and 240, for example. Of course, it should be understood that such shapes need not be considered inverted since an array of such shapes may not be considered inverted, depending on which portion of the array is viewed. Such a pyramidal shape is not limited to being four-sided. Other embodiments may include three-sided, or a pyramidal shape having more than four sides. Still other embodiments may include sides of a pyramidal shape that are truncated. Still other embodiments may include non-pyramidal shapes. For example, whereas a four-sided pyramidal shape has a square cross-section, and a three-sided pyramidal shape has a triangular cross-section, another embodiment may have a substantially circular cross-section, a substantially oval cross-section, and other shapes that may be manifested by various three-dimensional solar panel configurations. As shown in FIG. 2, individual light-collecting surface areas of individual solar panels 210, 220, 230, and 240 may face one another. In other words, the light-collecting surface of one or more such panels may be visible from the light-collecting surface of another such panel, as shown in FIG. 2, though claimed subject matter is not limited to the configuration of FIG. 2, as explained below. Herein, the term light-collecting surface refers to the surface area of a solar panel that collects light that is used to generate electricity. Such an area may also be referred to as an active region of a solar panel.

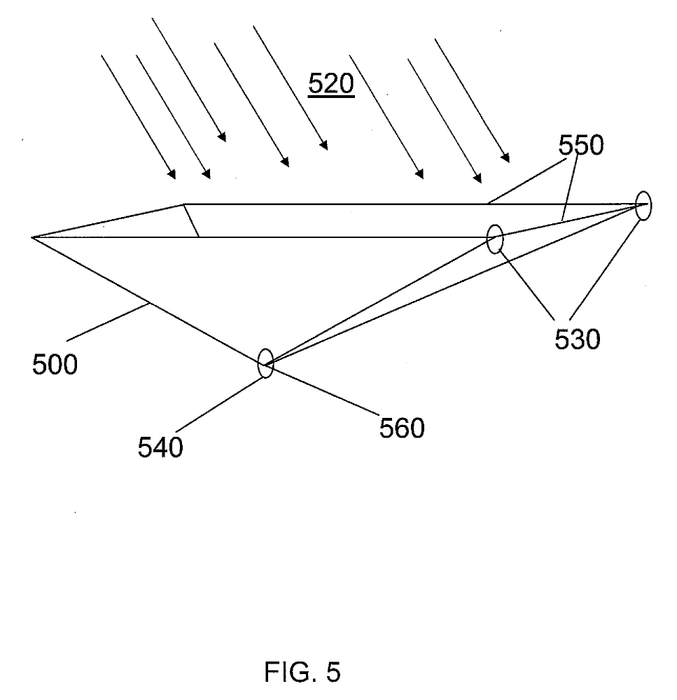

Perimeter 260 of solar panel 200 may define a surface area, which may include the footprint of solar panels 200. Such a footprint and its meaning are described above. A height “h” of solar panel 200 may be determined to optimize solar gain. For example, if “h” is too large, then solar panel surface area may be large but solar radiation may not reach lower portions of solar panel 200 (e.g., near apex 560, as shown in FIG. 5). On the other hand, if “h” is too small, solar radiation may reach all portions of solar panel 200 but surface area may not be significantly large.

Solar panel 200 may be placed next to one or more similarly-shaped solar panels. For example, FIG. 7 shows an array of such panels, which will be discussed further below.

Individual solar panels 210, 220, 230, and 240 may be coupled to one another electrically and/or mechanically, or such panels may be configured so that their respective electrical connections are separate. In a particular embodiment, one or more of individual solar panels 210, 220, 230, and 240 may be connected to one another along their respective edges. In another particular embodiment, individual solar panels 210, 220, 230, and 240 may be spaced apart and/or not connected to one another.

In another embodiment, solar panels 210, 220, 230, and 240 may comprise a single, or one or more solar panels. Such a single solar panel, for example, may be curved or bent to produce a pyramidal shape.

In an embodiment a “three-dimensional” solar panel 200 has an increased solar-receiving surface area compared to a flat solar panel 100 for a given perimeter area. Perimeter area, or footprint area, in this context may refer to an area of earth or roofing, for example, that either solar panel may cover. For example, in a particular embodiment, solar panel 200 may comprise a square pyramid having a height “h” and a square base with sides of length “s”. In such a case, the area of the base is s², which may be the same area as a flat solar panel 100 with a side of length “s”. But in the case of a pyramid shape, we have an additional area term, which is s(s²+4h²)^{1/2}. Accordingly, we may double, for example, the solar-gaining surface area of a solar panel by going from a flat solar panel 100 to a three-dimensional solar panel 200. Other shapes of solar panel are possible, such as a three-sided pyramid, and/or pyramids that do not necessarily have planer portions (e.g., sides. In other words, the sides of a pyramid may be curved or sagging, or faceted, for example) and so on, and claimed subject matter is not limited to a pyramidal shape. One may be concerned with an efficiency of packing in a two-dimensional space, for example, how tight can we pack our three-dimensional solar panels on a rooftop or the ground? Four and three-sided pyramids may be packed with 100% efficiency (see FIG. 7, for example), but other three-dimensional shapes may also have high packing efficiencies.

The idea of increasing solar gain is to increase surface area of solar panels while keeping the solar panels' footprint constant—this may include configuring solar panels with a third dimension, such as a depth. Pyramidal shapes compared to squares or triangles, for example, do this. And the pyramidal shapes may include angular sides to increase solar reception, compared to sides that are parallel to each other and do not pick up solar radiation as well.

In an embodiment, three-dimensional solar panels may comprise a shape similar to that of an egg carton, including the concave depression. Such an egg carton configuration is found in foam mattresses and packaging, for example. Three-dimensional solar panels may also use such a shape. Of course, this is merely an example, and claimed subject matter is not so limited.

If cloudy skies yield lower levels of solar radiation, then we can compensate by utilizing three-dimensional solar panels that have increased surface area compared to flat solar panels. Three-dimensional solar panels may not work as efficiently as flat solar panels positioned towards the sun during cloudless, sunny skies, but three-dimensional solar panels may work more efficiently than flat solar panels during cloudy skies.

Three-dimensional solar panels may actually provide an advantage to having cloudy skies compared to sunny skies: Flat solar panels generally require mechanical means to position the flat solar panels so that their surface is substantially perpendicular to the solar rays. Such positioning may be readjusted continuously throughout the day, as the sun changes position in the sky. Such mechanical means may be costly. On the other hand, three-dimensional solar panels need not be positioned to optimize their solar radiation reception because they work with cloudy days that produce scattered radiation. Accordingly, three-dimensional solar panels may not need any mechanical means to readjust their position relative to the position of the sun in the (cloudy) sky.

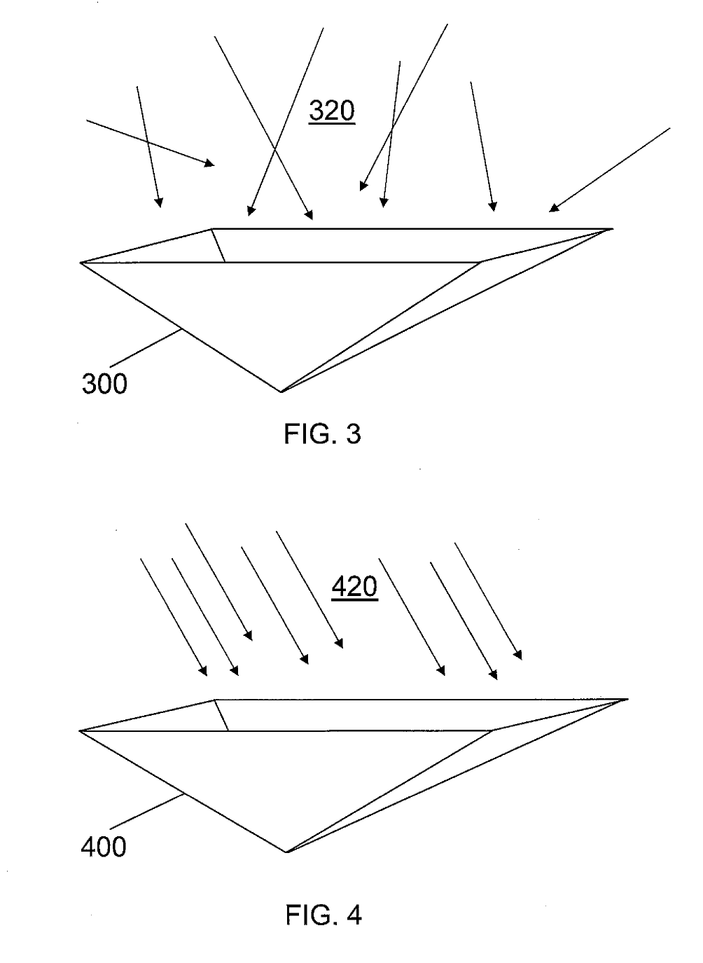

FIG. 3 is a schematic diagram illustrating scattered light rays incident on a solar panel 300, according to an embodiment. Solar panel 300 may be similar to that shown in FIG. 2, for example. During a cloudy day, for example, light rays from the sun may be scattered by the clouds. Such scattered light rays 320 may be incident on solar panel 300 from random directions. Because of the random scattered light directions, all individual solar panels 210, 220, 230, and 240 (FIG. 2) may receive substantially equal amounts of the scattered light 320. Or in another embodiment, all sides of solar panel 300 may receive substantially equal amounts of the scattered light 320. Of course, these are merely examples, and light may impinge on one individual panel more than another. Furthermore, claimed subject matter is not so limited.

FIG. 4 is a schematic diagram illustrating collimated light rays incident on a solar panel 400, according to an embodiment. On a sunny day, light from the sun may not be scattered by clouds, so that such light 420 is substantially collimated. In this case, one of the sides and/or portions of solar panel 400, or one of the individual solar panels 210, 220, 230, and 240 as in FIG. 2, may receive more light than other sides, portions, and/or panels. In an embodiment, solar panel 400 may be configured to change shape so that sides, or individual solar panels 210, 220, 230, and 240, may be positioned to receive as much light as possible. For example, individual solar panels 210, 220, 230, and 240 may change their respective position by means shown in FIG. 5, explained below.

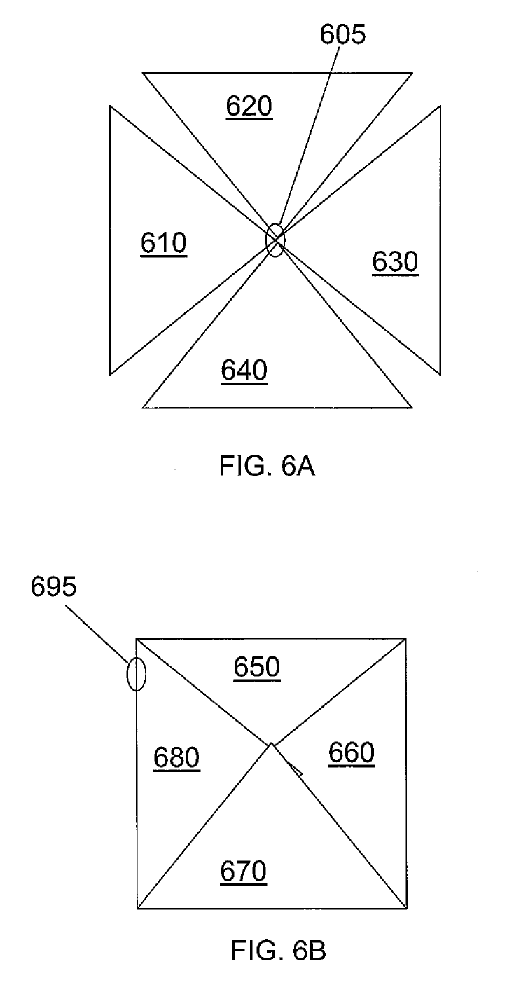

FIG. 5 is a schematic diagram illustrating a solar panel 500 enabled to change shape, according to an embodiment. Hinges or other mechanisms to enable angular position changes of individual solar panels 210, 220, 230, and 240 (FIG. 2) may be included with solar panel 500. In a particular implementation, hinges 540 may be placed at or near an apex 560 of individual solar panels 210, 220, 230, and 240 to allow the individual solar panels to rotate substantially about their apex. A piston or other mechanism (not shown) may be connected to another portion of the individual solar panels to drive a rotation about the hinge position at 560. In another particular implementation, hinges 530 may be placed at edges 550 of individual solar panels 210, 220, 230, and 240 to allow the individual solar panels to rotate about their edges. A piston or other mechanism (not shown) may be connected to another portion of the individual solar panels to drive a rotation about the hinge position at 550. FIG. 6 shows two embodiments of solar panel 500 laid flat by the action of pistons (not shown) and hinges), according to an embodiment, as explained below.

FIGS. 6A and 6B are schematic diagrams illustrating solar panels in a flat configuration, according to an embodiment. FIG. 6A may represent an embodiment of solar panel 500 with hinges 605 at the apexes of the individual solar panels 610, 620, 630, and 640. FIG. 6B may represent an embodiment of solar panel 500 with hinges 695 at the edges of the individual solar panels. In this latter embodiment, the panels may involve a sequence, wherein a first panel 650 is laid flat first (or begins an action of being laid flat first), then a second panel 660 is laid flat, then a third 680, and then a fourth 670, and so on, for example. In this way, the panels may not collide, as geometry dictates.

Solar panel 500, for example, may be laid flat during cloudless, sunny skies, when sunlight is substantially collimated. In this case, a flattened solar panel 500, as shown in either FIG. 6A or FIG. 6B, may be more efficient at capturing solar energy than the three-dimensional mode schematically illustrated in the embodiment of FIG. 5. But during cloudy days, a three-dimensional solar panel may be more efficient at capturing solar energy than a flattened mode shown in FIGS. 6A and 6B.

FIG. 7 is a schematic diagram illustrating an array 750 of solar panels 700, according to an embodiment. Such an array may be located in a field, a roof top, and so on. Perimeters of pyramidal-shaped solar panels, as described above, may be physically separated from a surface of a field or roof top on which such panels are mounted. This may be the case if an inward surface of the pyramidal-shaped solar panel is used to collect light to generate electricity. In such a case, as can be realized by viewing FIG. 7, array 750 may involve less surface contact between array 750 and a mounting surface (such as a roof top or ground) compared with mounting array 750 with pyramid perimeters contacting such a mounting surface (such as with array 750 upside down with respect to what is shown in FIG. 7). Packing of solar panels 700, which may be similar to solar panels 200 of FIG. 2, may be 100% efficient for pyramidal shapes, for example, while other shapes may provide less packing efficiency. Array 750 may include any number of solar panels, each of which need not be identical, for example.

In another embodiment, such three-dimensional solar panels, as shown in FIG. 2 for example, may be implemented on a physically unstable surface, such as on a floating vessel in the ocean. Such a vessel, or ship, may be rocked around by wave action. In such a situation, a three-dimensional solar panel may receive solar radiation relatively efficiently without involving its careful positioning and alignment, such as may be necessary for efficient operation of a flat solar panel. Accordingly, three-dimensional solar panels may work relatively well rigidly mounted to part of a sea-going vessel even while the vessel is rocked about my ocean waves. In a particular implementation, such three-dimensional solar panels, as shown in FIG. 2 for example, may be implemented on a physically unstable surface that may be a dock or other floating device in the ocean or other body of water. Such a floating surface may provide “real estate” for solar energy generation. Using land area may be difficult, so areas over water, such as lakes or oceans, may be an economical alternative. Though such a floating surface, having three-dimensional panels attached thereon, may be rocked around by wave action, three-dimensional solar panels may receive solar radiation relatively efficiently without involving their careful positioning and alignment, such as may be necessary for efficient operation of a flat solar panel. Accordingly, three-dimensional solar panels may work relatively well rigidly mounted to part of a sea-bound (or other body of water) floating platform even while the platform is rocked about by waves. Additionally, large bodies of water are often associated with cloudy skies, and three-dimensional solar panels work efficiently in such weather conditions, as explained above.

In another embodiment, such three-dimensional solar panels, as shown in FIG. 2 for example, may be implemented on a physically vertical surface, such as the side of a building, for example. During cloudy skies, scattered solar radiation is available in substantially all directions, so a vertical surface, or an area under cover from a direct line of sight to the sun's position, may receive such scattered solar radiation. Accordingly, three-dimensional solar panels are relatively efficient at receiving such scattered radiation. Such surfaces and/or areas may be economically used compared with surfaces on the ground or roofs.

In another embodiment, such three-dimensional solar panels, as shown in FIG. 2, may be implemented on ground-based vehicles, air-based vehicles, and any vehicle that changes is position relative to the sun. A weather balloon may implement such solar panels. Other vehicles may include planes, trains, and automobiles, just to list a few examples. In addition to vehicles, persons may wear clothing, for example, that have such three-dimensional solar panels mounted on such clothing. There are no size limits regarding these solar panels, so relatively small ones, perhaps configured in a matrix of such panels, may be placed on a person, an animal, and so on.

In an embodiment, such three-dimensional solar panels, as shown in FIG. 2, may be implemented inside buildings. Such interior spaces include indirect lighting from windows, skylights, and/or artificial lighting. Such indirect lighting may include scattered light, which may be received by three-dimensional solar panels, as described above. Interior space surfaces that may receive such three-dimensional solar panels may include furniture, walls, floors, structural elements, and/or any surface that may be found inside a building. Such surfaces outside a building may also receive such three-dimensional solar panels. Of course, these are merely some examples, and claimed subject matter is not so limited.

In an embodiment, such three-dimensional solar panels, as shown in FIG. 2, may be implemented on window coverings, such as curtains, blinds, and/or shades. Skylight coverings may also be considered in this regard. Such window coverings, as with other interior spaces, may include indirect lighting from windows, skylights, and/or artificial lighting. Such indirect lighting may include scattered light, which may be received by three-dimensional solar panels, as described above. In an implementation, such window coverings may be included in outdoor spaces.

In an embodiment, such three-dimensional solar panels, as shown in FIGS. 2 and 3, may be two-sided. That is, such solar panels may be configured to receive light on both opposite surfaces. Energy may be generated from both sides. For example, FIG. 8 shows that light 820 and 840 may be received on both sides of three-dimensional solar panel 800. To simplify description herein, and in terms of FIG. 8, the term “inward side” means the side of solar panel 800 that is receiving light 820, whereas the term “outward side” means the side of solar panel 800 that is receiving light 840. Such terms may also be used to describe other embodiments of a three-dimensional solar panel described above, such as for solar panels 200, 300, 400, and 500. For example, in FIG. 3, light 320 is shown incident on the inward side of solar panel 300. Accordingly, returning to FIG. 8, solar panel 800 may generate electricity by both receiving light 820 from its inward side and receiving light 840 from its outward side. Energy generation may be relatively efficient by capturing scattered light from many different directions on both sides of such a panel.

It should be understood that, although particular embodiments have been described, claimed subject matter is not limited in scope to a particular embodiment or implementation. Though the word “panel” is used, it should be understood that panel in the context of this disclosure is not limited to a plane structure, unless explicitly described as so. Further, a panel may comprise one or more individual units, be built from one or more separate structures, and/or comprise a single structure with folds and/or bends to result in a three-dimensional structure. Claimed subject matter is not so limited.

It should be understood that solar panel may refer to a material and/or a structure that is able to generate energy, particularly electricity, from light. Such light may be natural, as in sunlight, or artificial. Also, the term “solar” in “solar energy” should be understood to not be limited to that pertaining to the sun. Artificial light may apply in this context as well.

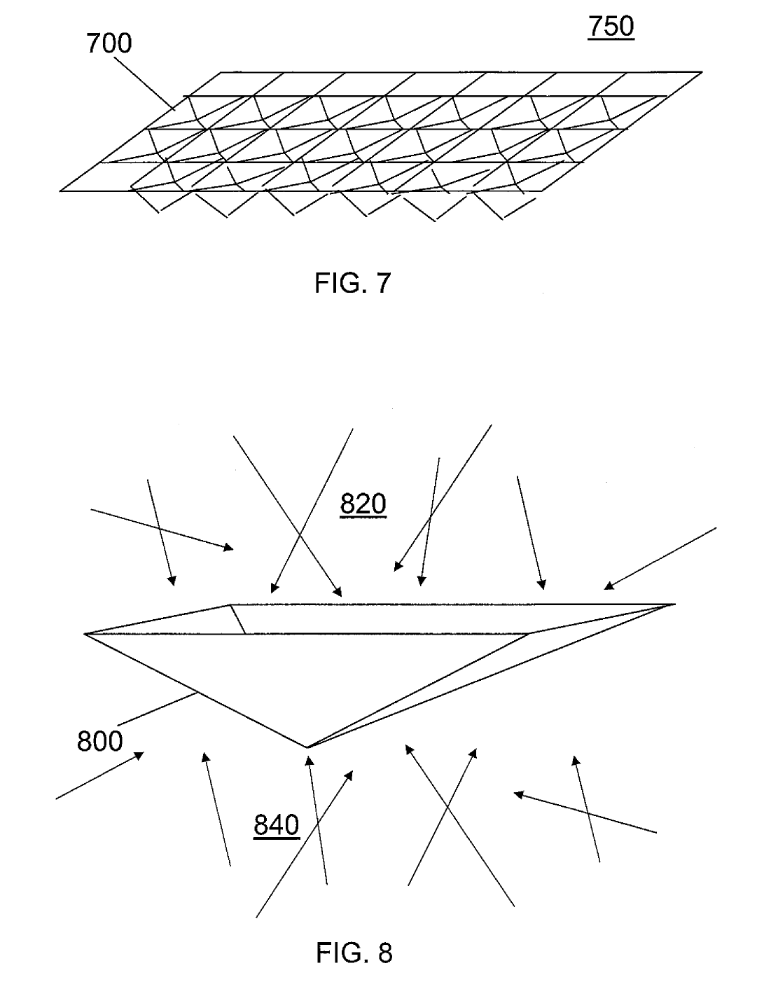

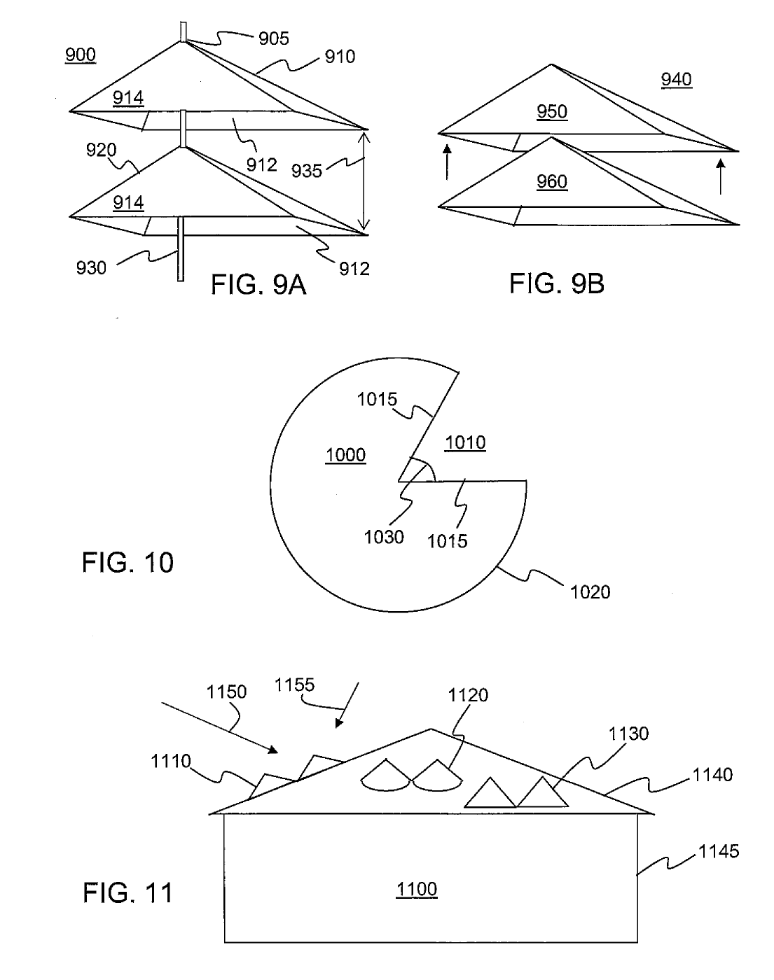

FIGS. 9A and 9B are perspective views showing multiple three-dimensional solar panels in a stacked configuration, according to embodiments. For example, one or more solar panels may be supported by a pole and arranged about the pole to receive light from multiple directions about the pole. Such multiple directions may include cardinal directions (e.g., north, south, east, and west), or variants thereof. For example, such light may comprise scattered light similar to scattered light 820 and/or 840 shown in FIG. 8. As explained above, a benefit of a multiple three-dimensional solar panel may be that such a panel may provide surfaces comprising photovoltaic (PV) cells to receive light from multiple directions. Scattered sunlight on a cloudy day, for example, may shine in such multiple directions. Solar panels may be arranged about a pole to receive light from multiple radial directions about the pole (again, including the cardinal directions, for example). A solar panel pole 900, as described in detail below, may provide a benefit in that multiple three-dimensional solar panels may be arranged in a relatively small area of surface (e.g., land or rooftop). Examples are provided below to demonstrate that relatively high numbers of such solar panels may be deployed in a relatively small area.

In detail, FIG. 9A shows a solar panel pole 900 comprising three-dimensional solar panels 910 and 920 (which need not be identical to one another) mounted to a shaft or pole 930. Even though such solar panels are drawn to have pyramidal shapes in FIG. 9A, embodiments discussed herein are not intended to be limited to such shapes. For example, solar panels 910 or 920 may comprise conical shapes and so on, as described below. Also, solar panel pole 900 need not be oriented in a vertical direction, and claimed subject matter may include any angle relative to gravity or the sun, for example. Also, solar panel pole 900 need not comprise a shaft or pole 930 that penetrates an apex 905 of solar panels. For example, brackets or other types of mechanical devices may be used to fix multiple solar panels together in place of pole 930. In another example, two or more rods or poles may be used to support solar panels 910, 920, wherein such rods or poles penetrate the solar panels at locations offset from apexes of the solar panels.

Solar panels 910 and 920 may be positioned a distance 935 apart, which may be determined for a particular application or conditions at hand. For example, spacing 935 may be determined based, at least in part, on location (e.g., latitude), size, or relative dimensions of solar panels 910 or 920, and so on. In particular, distance 935 may be determined so that a desirable amount of light, which may comprise scattered light, may reach a relatively large portion of surface area of solar panels 910 or 920. There may be a trade off between the number of solar panels that may be placed on a pole and the amount of light that reaches the solar panels. Even scattered light may include shadowing. For example, if distance 935 is too small, solar panel 910 may substantially shadow (e.g., block light to) solar panel 920, though a relatively large number of solar panels (e.g., in addition to solar panels 910 and 920) may be included on a single pole (e.g., packing efficiency). On the other hand, if spacing is too large, solar panel 910 may no longer shadow (e.g., block light) to solar panel 920, but a single pole may have a capacity for relatively few solar panels (e.g., in addition to solar panels 910 and 920).

If multiple solar panel poles 900 are to be considered, then spacing between or among the solar panel poles may be determined based on latitude, season, trade-off between packing efficiency and light gathering efficiency (e.g., a first solar panel pole may block light to a second solar panel pole), just to name a few examples. In one implementation, such solar panel poles may be arranged in a row. In another implementation, such solar panel poles may be arranged in an array (e.g., multiple rows), for example.

In one implementation, an area of land (or other surface) may include multiple poles 930 that individually include one or more three-dimensional solar panels. For a numerical example, such a pole may have a height of twenty feet and include five three-dimensional solar panels 910 or 920 spaced apart (e.g., distance 935) by about four feet along the pole (e.g., distance from the apex of one solar panel to the apex of the next solar panel). Such solar panels may have a base and/or diameter of about four feet. With such numbers or dimensions as in the present example, an acre of land may include about five-hundred solar panels on one-hundred solar panel poles spaced apart by about twenty feet in a 10×10 array. Such spacing may be the case for a location at a latitude of about 45 degrees (for latitudes closer to the equator, solar panel poles may be spaced closer since the sun is at a relatively high angle so that shadowing of one solar panel pole to another is relatively less). However, considering that solar panel poles 900 may comprise solar panels that are adapted to receive scattered light from multiple directions (e.g., on a cloudy day scattered sunlight may be received on solar panels 910, 920 from northerly directions in addition to southerly directions, and so on), solar panel poles in an array may be arranged closer together with relatively little concern for direct sunlight shadowing. For example, an acre of land may include about two-thousand solar panels on four-hundred solar panel poles spaced apart by about ten feet in a 20×20 array. Of course such numbers are merely examples, and claimed subject matter is not limited to any particular numbers or quantities.

In a particular implementation, solar panels 910, 920 may comprise pyramidal solar panels, such as solar panel 200 shown in FIG. 2, for example. In another particular implementation, such solar panels may comprise conical solar panels, such as those shown in FIGS. 10 and 11 and described below, for example. In yet another particular implementation, such solar panels may comprise PV cells mounted on an inside surface, an outside surface, or both inside and outside surfaces of solar panels 910, 920, such as the situation shown in FIG. 8, for example. To illustrate, PV cells may be mounted on inside surface(s) 912, on outside surface(s) 914, or both inside and outside surfaces of solar panels 910 and/or 920. Thus, reflected light (which may comprise a portion of light impinging on a PV cell that is not absorbed by the PV cell, for example) from an outside surface 914 of solar panel 920 may impinge on inside surface 912 of solar panel 910. In such a fashion, what may have otherwise been “wasted” light reflected from PV cells on solar panel 920 may be utilized by adjacent solar panel 910. A benefit of such an arrangement may be that PV cells of solar panels 910, 920 need not include relatively expensive anti-reflection (AR) coatings, since reflected light may be utilized (e.g., converted to electricity). Also, even AR coated PV cells may reflect a portion of incident light. Solar panel pole 900 may utilize such reflected light. In addition, solar panel pole 900 may provide a benefit in that a relatively large amount of scattered light may be received to generate electricity by virtue of a relatively large amount of solar panel surface area, and need not include lenses or other collimating devices. Of course, such details and benefits of solar panel poles 900 are merely examples, and claimed subject matter is not so limited.

In a particular implementation, an apparatus (e.g., that shown in FIG. 9A) may comprise two or more solar panels arranged above or below one another, and a pole to support the two or more solar panels, wherein the pole penetrates an apex of at least one of the two or more solar panels. In one particular example implementation, two or more of the solar panels may comprise PV cells on inside and outside surfaces of the two or more solar panels. For example, a concave side of the solar panels comprises the inside surfaces, and wherein a convex side of the solar panels comprises the outside surfaces. Two or more of the solar panels may comprise substantially pyramidal shaped solar panels or comprise substantially conical shaped solar panels, though claimed subject matter is not so limited.

FIG. 9B shows an aspect of three-dimensional solar panels that may provide a benefit of packaging or shipping efficiency of such panels. In particular, two or more solar panels 950 and 960, which may have a substantially pyramidal or conical shape, for example, may be arranged in a stacked configuration during shipping or while packaged for retail. As shown, three-dimensional solar panel 960 may fit inside three-dimensional solar panel 950 in stacked arrangement 940. Such three-dimensional solar panels 950 and 960 may be similar to solar panel 200 shown in FIG. 2, for example. Though flat solar panels may also be stacked upon one another during shipping or packaging, three-dimensional solar panels have a relatively larger area to collect additional light, which may comprise scattered light, as explained above. In one implementation, solar panels 950, 960 (or 910, 920) may comprise a rigid material that includes PV cells, though claimed subject matter is not so limited.

FIG. 10 is a plan view showing a conical solar panel 1000 in a flattened configuration, according to an embodiment. Such a solar panel may comprise a pliable or flexible material that includes one or more PV cells so that flattened solar panel 1000 may transition to a conical three-dimensional solar panel, such as that shown positioned on a rooftop in FIG. 11 below, for example. In detail, flattened solar panel 1000 may include a gap 1010 having edges 1015 and a perimeter 1020. In a process to transition flattened solar panel 1000 to a conical solar panel, edges 1015 may be brought together or connected to each other, thus substantially closing gap 1010. Upon doing so, the flexible material and PV cells may be configured to a conical shape solar panel. A conical shape may provide a benefit in that such geometry may provide substantially rigidity or structural integrity even if the conical shape comprises a substantially flexible material. In one implementation, such flexible material may comprise sheet metal or sheet plastic, just to name a few examples.

Dimensions of such a conical-shaped solar panel, such as height or base diameter, may be based, at least in part, on gap angle 1030 and/or perimeter 1020, for example.

For a particular numerical example, flattened solar panel 1000 may comprise a gap angle 1030 of about 150 degrees, a perimeter 1020 of about 24 feet, so that a resulting cone may have a height of about 3 feet. Such a conical-shaped solar panel may provide benefits similar to those of other three-dimensional solar panels (e.g., a relatively large surface area to collect scattered light). For example, solar panel 1000 comprising a conical shape may provide a relatively large surface area on which to place PV cells to receive scattered light. Though a conical solar panel may result in an increased amount of light received, lenses or other collimating devices need not be used. Another benefit may be that conical-shaped solar panels may be shipped or packaged in a flattened configuration for shipping or packing efficiency, for example. Upon purchasing or otherwise receiving such flattened solar panels 1000, a professional installer or non-professional person (e.g., a home owner or do-it-yourselfer) may assemble the flattened solar panels 1000 into a conical configuration with relative ease. In one implementation, a solar panel pole such as solar panel pole 900 in FIG. 9 may comprise conical solar panels. In such a case, such conical solar panels need not comprise a pliable or flexible material or need not be assembled from a flattened conical shape, as described above. Of course, such numbers and details of solar panel 1000 are merely examples, and claimed subject matter is not so limited.

In a particular implementation, a material comprising PV cells may comprise a substantially flat flexible material having a shape that includes a gap, wherein the gap includes edges that if brought together to close the gap, may result in the flat flexible material comprising a cone-shaped solar panel.

FIG. 11 is a side view showing a roof 1140 of a building (e.g., a house) 1100 including various types of three-dimensional solar panels, according to an embodiment. In particular, in one implementation, one or more conical-shaped solar panels 1120 may be mounted on roof 1140 or wall 1145. Such conical-shaped solar panels 1120 may be similar to solar panels 910, 920 shown in FIG. 9A, for example. In another implementation, one or more pyramid-shaped solar panels 1130 may be mounted on roof 1140. Such pyramid-shaped solar panels 1130 may be similar to solar panels 910, 920 shown in FIG. 9A, for example. Solar panels 1110 shown in side view in FIG. 11 may comprise conical or pyramid shaped solar panels, or other shaped three-dimensional solar panels, for example. Details of techniques to mount such three-dimensional solar panels to a roof or other surface are described below.

As discussed above, three-dimensional solar panels may provide a benefit in that such solar panels may include a relatively large surface area to receive scattered light, which may result from cloudy or rainy weather. For example, solar panels 1110 may comprise surface area portions to receive light 1150 or light 1155 at the same time. On the other hand, to compare, a flat solar panel may occupy the same area of roof as the base of solar panel 1110. A flat solar panel may also receive light 1150 and 1155. But surface area of such a flat solar panel may be substantially less than that of three-dimensional solar panel 1110. Therefore, a flat solar panel may accommodate substantially less PV cell area compared to solar panel 1110 for the same roof area, for example. In an implementation, described in detail below, solar panel 1110 may provide thermal insulation to building 1100, particularly if a base of solar panel 1110 is in substantial contact with roof 1140. In another such implementation, solar panel 1110 may provide thermal insulation to building 1100 via walls 1145 if a base of solar panel 1110 is in substantial contact (e.g., mounted on wall 1145) with wall 1145, for example.

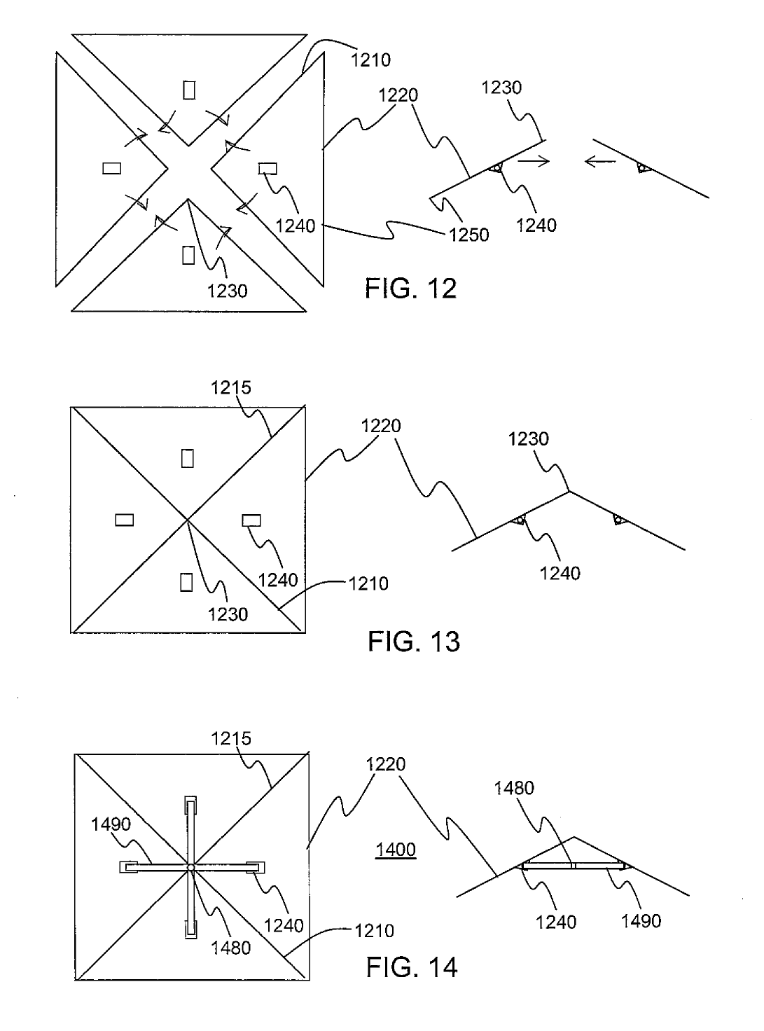

FIGS. 12-14 show top and cross-sectional views of components and a process of assembling a three-dimensional solar panel, according to an embodiment. Figures on the left are top views and figures on the right are cross-sectional views. In an implementation, a three-dimensional solar panel having a pyramidal shape may be shipped, stored, and/or sold in sections 1220. Such sections may comprise a rigid material at least partially covered with one or more PV cells. FIG. 20 shows a detailed view of a portion of a three-dimensional solar panel which may be similar to section 1220, for example. Sections 1220 may include edges 1210 that may join at apex 1230, which may comprise an apex of a pyramidal shape after assembly. Edges 1210 may form seams 1215 of the assembled pyramid if edges 1210 of sections 1220 are brought together, as indicated by small arrows in FIG. 12. Edges 1210 of sections 1220 may be held together by any of a number of possible techniques, such as bolts, snaps, ties, Velcro, zippers, tongue and groove seams, tape, just to name a few examples. Perimeter edges 1250 may form a perimeter at the base of the assembled pyramid, for example. Sections 1220 may include a bracket 1240 located in a mid-portion of section 1240, though claimed subject matter is not limited to such a location. In FIG. 14, structural integrity of the assembled pyramidal-shaped solar panel 1400 may be improved using a cross-bar 1490 that connects to brackets 1240. Additional brackets and/or other mechanical components may be used, though not shown. For example, in applications in areas prone to high winds, additional strength may be desired. Cross-bar 1490 may include a hole 1480 to accommodate a bolt, as explained below. Again, for additional strength, additional holes or bolts may be used, though not shown in the figures.

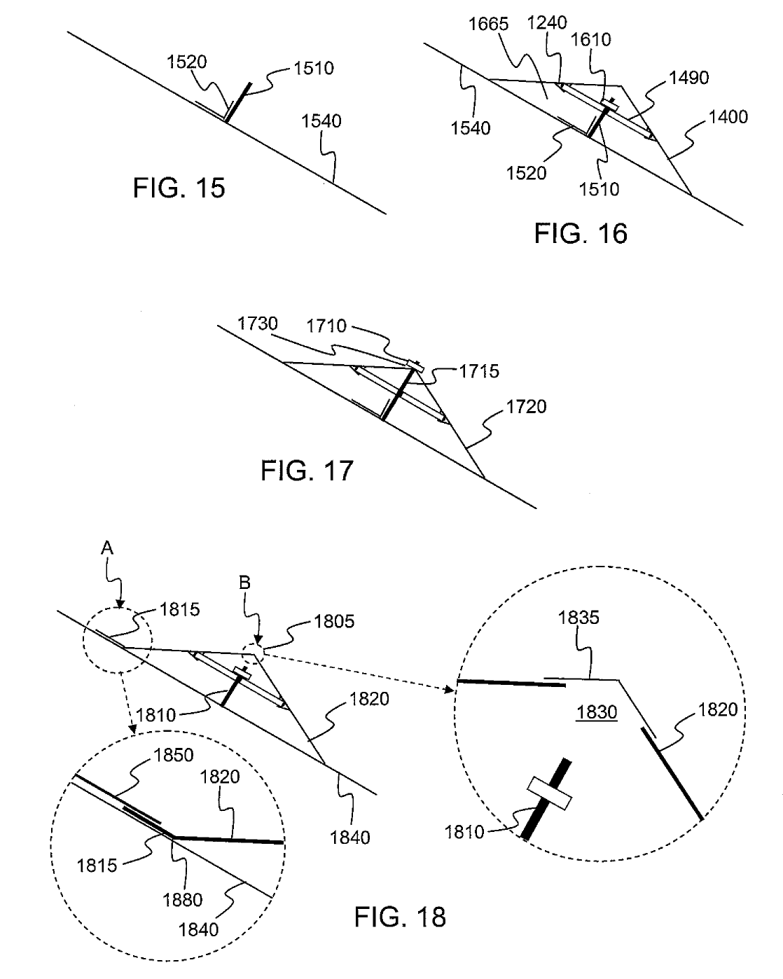

FIGS. 15-16 show cross-sectional views of components and a process of mounting a three-dimensional solar panel to a surface, according to an embodiment. For example, assembled pyramidal-shaped solar panel 1400 may be mounted on a surface 1540, which may comprise a wall or rooftop. In another example, assembled cone-shaped solar panel 1110 may be mounted on a surface 1540. Though the following discussion includes pyramidal-shaped solar panel 1400, the following process may include other shaped solar panels including a cone shaped solar panel, for example. Such a process may provide a benefit in that solar panel 1400 may provide substantially rain-tight cover over locations where roof penetrations (and thus susceptibility to leaks) may occur. Also, solar panel 1400 may provide substantial thermal insulation to a building that includes surface 1540. Such insulation may result from R-values of solar panel material and/or an air gap 1665 between solar panel 1400 and surface 1540. For example, solar panel 1400 (or any three-dimensional solar panel described herein) may comprise a substrate or insulative material onto which PV cells may be placed. In one implementation, a hollow region or air gap 1665 may be filled with a material (e.g., foam, fiberglass, polystyrene, cellulose) to add additional R-value. For a numeric example, solar panel 1400 may provide an R-value in a range of about 1 to 40 or more, though claimed subject matter is not so limited.

In a particular implementation, a bolt 1510 may extend outward from surface 1540. In another implementation, bolt 1510 may extend outward from a mounting framework (not shown) that may be attached to surface 1540. In the case of a roof surface, for example, flashing 1520 may be used to shed rain water away from a location where bolt 1510 is affixed to the roof (or penetrates the roof material, for example). In FIG. 16, assembled pyramidal-shaped solar panel 1400 may be placed over bolt 1510 so that bolt 1510 inserts through a hole in cross-bar 1490. Solar panel 1400 may be secured to the bolt (and thus to surface 1540) using a washer and nut 1610 as shown in the figure. Of course such details are merely illustrative examples and any number of variations is possible. In another embodiment, FIG. 17 shows that a relatively long bolt 1715 may extend through a cross-bar or an apex 1730 of a solar panel 1720, and be secured using washer and bolt 1710, for example.

FIG. 18 shows a cross-sectional view and detailed views of a three-dimensional solar panel mounted to a surface, according to yet another embodiment. For example, a solar panel 1820 may be affixed to a surface 1840, similar to that shown in FIG. 16. However, solar panel 1820 may include flashing 1815 at a perimeter or base of solar panel 1820. In one implementation, flashing 1815 and a portion of solar panel 1820 may comprise a continuous membrane to prevent rain water (for example) from flowing beneath solar panel 1820 in a region near bolt 1810. For example, inset detail A shows an implementation wherein flashing 1815 placed onto a surface 1840 may be integrated with solar panel 1820 at a perimeter or base 1880 of the solar panel. In such an application, a roof shingle 1850 may be placed over a portion of flashing 1815 so that solar panel 1820 may be mounted on a roof in a rain-proof fashion. Flashing 1520 or 1815 may comprise a sheet material of metal, plastic, or asphalt impregnated composite, just to name a few examples. For a particular example, dimensions of flashing 1520, 1815, bolt 1510, 1810, crossbar 1490, and so on may be in the order of inches, though claimed subject matter is not so limited.

Inset detail B shows an apex region of solar panel 1820, which may include a removable portion 1835. Access to bolt 1810 may be accomplished via opening 1830 by removing portion 1835. Though solar panel 1820 (or solar panel 1720 or solar panel 1220) has been described as having a pyramidal shape, embodiments described herein may be applied to solar panels having other shapes, such as conical shapes, dome shapes (e.g., hemispherical), and so on. Also, such details discussed herein are merely examples, and claimed subject matter is not so limited.

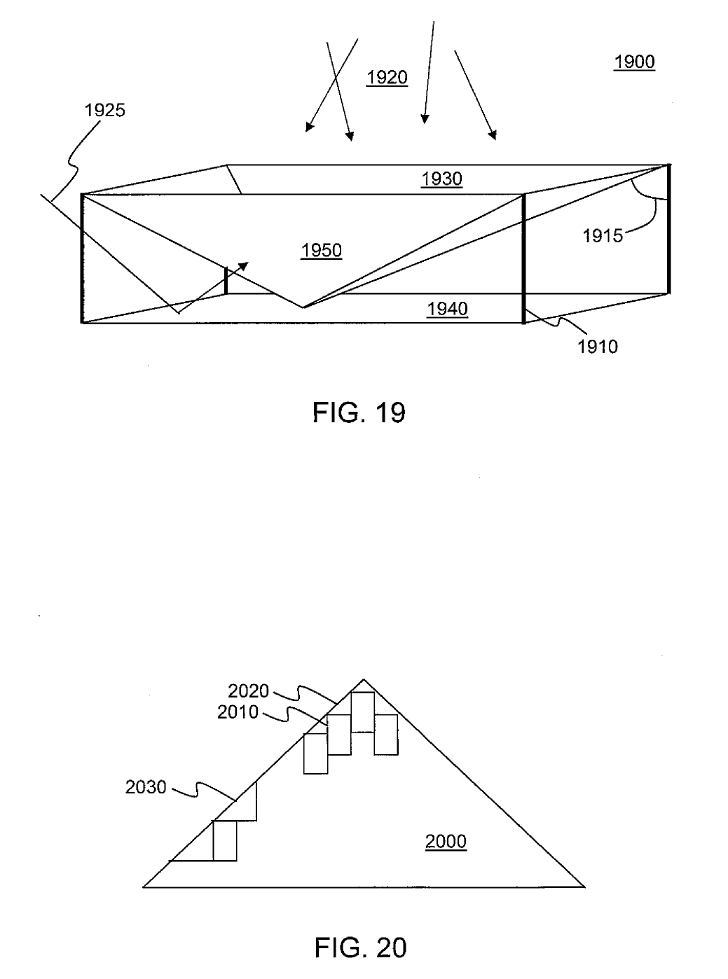

FIG. 19 is a perspective view showing of a three-dimensional solar, according to an embodiment. Such a three-dimensional solar panel may comprise an inverted pyramidal shape similar to that shown in FIGS. 2-4, for example. An inverted three-dimensional solar panel 1900 may be mounted to a surface 1940 using one or more supports 1910. In one implementation, surface 1940 may comprise an area including PV cells or a reflecting surface to absorb and/or reflect light 1925. Such light may subsequently impinge on outside surface 1950 of solar panel 1900. Meanwhile, other light 1920 may impinge on inside surface 1930 of solar panel 1900. For example, such a solar panel may include PV cells on inside surface 1930, on outside surface 1950, or both, as explained above regarding FIG. 8. An angle associated with slope of solar panel 1900 may be selected so that light 1925 and 1920 may impinge on inside or outside surfaces 1930 and 1950 by a relatively large amount. As described above, light 1925 and 1920 may comprise scattered light that may shine on both inside surface 1930 and surface 1940 (and subsequently reflected to outside surface 1950, for example). Accordingly, solar panel 1900 may comprise a relatively large PV cell surface area to collect a relatively large amount of scattered light.

FIG. 20 is a schematic diagram illustrating photo-voltaic cells arranged on a surface, according to an embodiment. In various embodiments described herein, solar panels may comprise shapes that need not be rectilinear. For example, PV cells 2010 may comprise a substantially rectangular or square shape, whereas a solar panel area 2000 may comprise an angular shape. Such a geometrical mismatch may lead to gaps 2020 so that only a portion (albeit a relatively large portion) of solar panel area 2000 may be utilized. In one implementation, angular-shaped PV cells 2030 may be used to avoid gaps 2020. Three-dimensional solar panels described herein may comprise solar panels and/or PV cells similar to that shown in FIG. 20, for example. In one implementation, solar panel area 2000 may comprise a rigid material. In another implementation, solar panel area 2000 may comprise a flat geometry. In another implementation, solar panel area 2000 may comprise a curved geometry, such as that used for a conical solar panel, for example. Accordingly, although an embodiment described herein may include a particular shape of solar panel, the area of such a solar panel need not be completely covered with PV cells. Of course, claimed subject matter is not limited to such examples or details.

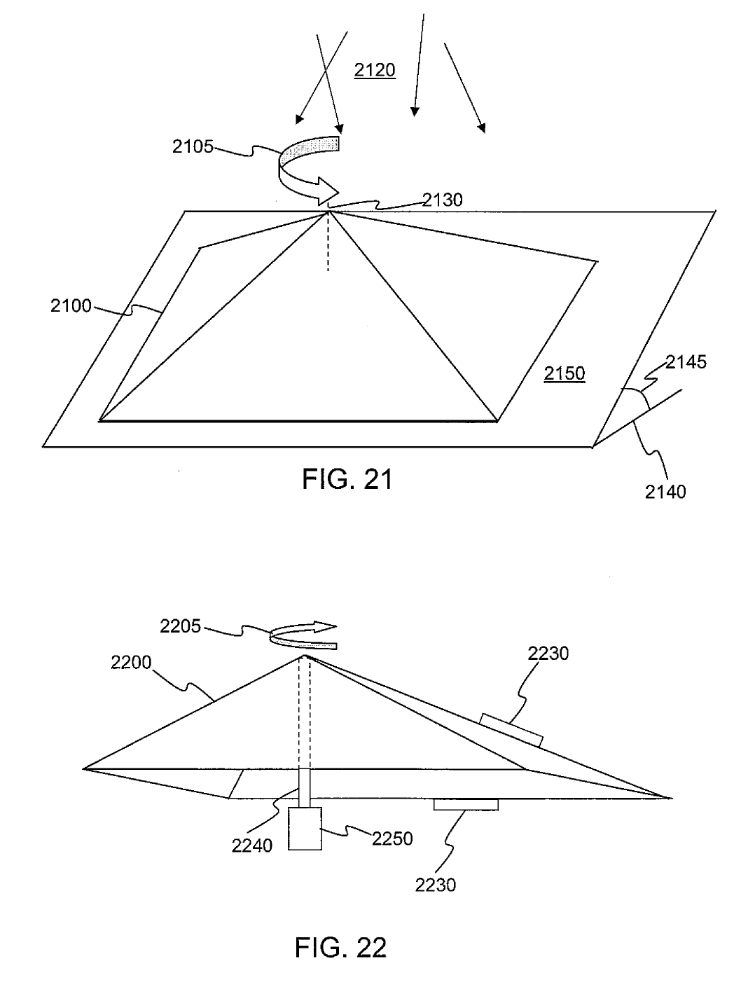

Embodiments described herein, in FIGS. 21-30, for example, are directed to rotatable solar panels. Such rotatable solar panels may rotate by at least a complete revolution, for example. Such rotatable solar panels need not include solar trackers that track the sun as the earth rotates. Instead, such rotatable solar panels may rotate or spin on an axis independently of the sun's position in the sky, for example. An ability to rotate may provide techniques to determine whether light incident upon a rotatable solar panel is predominantly collimated or scattered. Techniques to carry out such a determination may lead to a number of implementations. In one implementation, for example, a rotatable solar panel may be used to detect and/or determine characteristics of the sky and/or weather, whether the sky is sunny, partially cloudy, completely cloudy, foggy, smoky, smoggy, and so on and/or whether the sky includes particular particles or chemicals (e.g., carbon dioxide, water vapor, and so on). In another implementation, for example, a rotatable solar panel may be used to generate electrical energy at a desirable (e.g., optimal) efficiency (e.g., light gathering efficiency) by determining, among other things, whether incident light is predominantly collimated or scattered. In such an implementation, as explained in detail below, a rotatable solar panel may comprise a rotatable three-dimensional solar panel, which may rotate in scattered light conditions or be held in a particular rotational position in collimated light conditions. In yet another implementation, for example, a rotatable solar panel may be used in an ornamental application that may also generate electricity via solar power. For example, a rotatable solar panel may attractively spin in wind, and concurrently generate electricity.

As explained in detail below, a rotatable solar panel may rotate while receiving light or generating electrical power. Magnitude of such generated electrical power may vary or modulate depending, at least in part, on whether the rotatable solar panel is operating under a sunny or cloudy sky. Unless otherwise specified, the term “cloudy” may include other light-scattering conditions, such as smoky, foggy, rainy, and so on. Sunny skies may lead to substantially collimated (e.g. direct) sunlight so that a rotating solar panel may produce electrical power having a modulating intensity. Such modulated intensity may result from the fact that an amount of received light may depend relatively strongly on orientation of a rotating solar panel. On the other hand, gray skies may lead to substantially scattered sunlight so that a rotating solar panel may produce electrical power having a relatively constant intensity (or relatively low modulation), since scattered sunlight may be omni-directional or received from a variety of directions at the same time. Thus, an amount of received light may not depend strongly on orientation of a rotating solar panel. In one implementation, a degree of modulation may be associated with a degree of cloudiness to determine weather and/or sky conditions. For example, thick clouds, heavy smoke, or heavy fog may scatter light to a greater extent than light clouds or light smoke or fog, in which case prevailing sunlight may comprise some scattered light and some direct sunlight. In another implementation, such modulation may be used to determine an optimal electrical-generating position of a rotatable three-dimensional solar panel that is producing the modulation. In such a case, a configuration of rotatable three-dimensional solar panels may include a mechanism to allow rotation of the rotatable three-dimensional solar panels and/or to lock the rotatable three-dimensional solar panels into a particular position.

Three-dimensional solar panels may comprise solar panels (e.g., comprising solar cells, PV cells, and so on) that simultaneously face two or more different portions of the sky. For example, a pyramidal-shaped three-dimensional solar panel may include three or more sides that individually face three different portions of the sky at the same time. In a counter example, one or more solar panels all facing a substantially same portion of the sky at the same time may comprise a substantially flat solar panel that is not three-dimensional.

In one implementation, a solar panel may comprise one or more photo-detectors and/or PV cells positioned on a weather vane, such as a rotatable wind gauge, so that the one or more photo-detectors and/or PV cells face different portions of the sky at different times. As in the example above, an embodiment of rotatable solar panels may comprise such one or more photo-detectors and/or PV cells positioned on a rotating structure such as a rotating wind gauge.

FIG. 21 is a perspective view showing a rotatable three-dimensional solar panel 2100, according to an embodiment. Such a solar panel may provide a benefit in that particular rotational positions about an axis may lead to a desired amount of received light for generating solar power. Thus, solar panel 2100 may be rotated (or allowed to rotate) until such a position is determined. Solar panel 2100 may provide another benefit in that rotation may provide a solar signal that modulates according to sky conditions, as described in detail below.

In one implementation, three-dimensional solar panel 2100 may comprise a pyramidal shape, such as that shown in FIG. 2, for example. In the case shown in FIG. 21, three-dimensional solar panel 2100 may comprise solar panels that are oriented to receive light 2120, which may comprise scattered and/or collimated light. Herein, though the term “collimated light” is used, such a term need not imply that a lens or other collimating device is used to produce collimated light. But rather, collimated light refers to non-scattered light. For example, direct sunlight or light shining from an artificial light source may comprise collimated light. In one implementation, three-dimensional solar panel 2100 may comprise a non-inverted pyramidal shape positioned on surface 2150 (e.g., a rooftop). An angle of inclination 2145 from horizontal 2140 may comprise an angle in a range from zero to 90 degrees (vertical) or in a range from 90 to 180 degrees (e.g., upside down or inverted). In an implementation incorporating any such angle, PV cells may be located on the inside (e.g., concave) and/or outside (e.g., convex) portion of a pyramidal shaped three-dimensional solar panel 2100. As indicated by arrow 2105, three-dimensional solar panel 2100 may rotate (e.g., clockwise or counterclockwise) about an axis 2130 that intersects the apex of a pyramidal shaped three-dimensional solar panel or any other shaped three-dimensional solar panel. Axis 2130 may correspond to a rotatable shaft or other such structure.

FIG. 22 is a perspective view showing a rotatable three-dimensional solar panel 2200, according to another embodiment. In one implementation, solar panel 2200 may rotate by an applied torque due to wind, for example. In another implementation, solar panel 2200 may be rotated by an applied torque from an electric motor, for example. Such implementations are described in detail below.

In one implementation, three-dimensional solar panel 2200 may be similar to that shown in FIG. 21, for example. Three-dimensional solar panel 2200 may comprise a non-inverted or inverted pyramidal shape positioned on a surface such as a rooftop (not shown), for example. A shaft 2240 may provide a rotational degree of freedom to allow three-dimensional solar panel 2200 to rotate clockwise or counterclockwise, as indicated by arrow 2205. In one implementation, shaft 2240 may be rigidly attached to solar panel 2200. Accordingly, shaft 2240 and solar panel 2200 may rotate together. In another implementation, shaft 2240 may be rigidly attached to a base, ground, or other stationary object and solar panel 2200 may be rotationally connected to the shaft. Accordingly, shaft 2240 may be stationary while solar panel 2200 may rotate. In yet another implementation, rotation of shaft 2240 and solar panel 2200 may be initiated by a mechanism 2250 that may comprise a motor, for example. In still another implementation, mechanism 2250 may comprise a combination of bearings and/or a motion-locking mechanism to suspend rotation of shaft 2240 (and thus to suspend rotation of three-dimensional solar panel 2200, for example). In still another implementation, rotation of shaft 2240 or solar panel 2200 may be initiated by air, gas, and/or fluid incident on a tab or sail 2230. For example, such air, gas, and/or fluid may comprise wind, water, and/or other gas or fluid capable of setting rotatable three-dimensional solar panel 2200 into rotational motion by impinging on surfaces of sails 2230. Sails 2230 may comprise one or more rigid and/or flexible structural appendages to “capture” a flow of air, gas, and/or fluid (e.g., wind) to impart a torque on rotatable three-dimensional solar panel 2200. For example, a relatively small flat or concave sheet of metal or plastic may act as a sail to capture a relatively light breeze on a rooftop. In one implementation, sail 2230 may comprise one or more such structural appendages located on top and/or bottom portions of rotatable three-dimensional solar panel 2200. In FIG. 22, for example, one sail 2230 may be positioned along an edge of a top portion of rotatable three-dimensional solar panel 2200 and another sail 2230 may be positioned along an edge of a bottom portion of rotatable three-dimensional solar panel 2200. In such cases, as mentioned above, mechanism 2250 may comprise a motion-locking mechanism to suspend rotation of shaft 2240 and solar panel 2200 in a presence or absence of such torque-producing air, gas, and/or fluid impinging on sails 2230.

In one embodiment, rotatable three-dimensional solar panel 2200 may be positioned on a rooftop (e.g., see FIG. 21) so that an apex of the rotatable three-dimensional solar panel 2200 may be pointed upward toward the sky. In such a case, PV cells may be located on the outward (e.g., convex) side of the rotatable three-dimensional solar panel 2200. However, in another embodiment, rotatable three-dimensional solar panel 2200 may be positioned on a rooftop so that the apex of the rotatable three-dimensional solar panel 2200 is pointed downward toward the rooftop. In such a case, PV cells may be located on the inward (e.g., concave) side of the rotatable three-dimensional solar panel 2200. Orientation of rotatable three-dimensional solar panel 2200 in FIG. 22 need not be limited to any particular direction. In addition, shaft 2240 may be located on the inside of rotatable three-dimensional solar panel 2200, as shown in FIG. 22, and/or located on the outside of rotatable three-dimensional solar panel 2200, where mechanism 2250, which may comprise a motor, may also be located. Of course, such details of solar panel 2200 are merely examples, and claimed subject matter is not so limited.

In one implementation, rotatable three-dimensional solar panel 2200 may comprise dimensions of the order of inches, feet, and or yards. For example, a rooftop may include one or more such rotatable three-dimensional solar panels that may comprise an area of several square feet or 10, 20, or more square feet. Of course, claimed subject matter is not limited to any particular size.

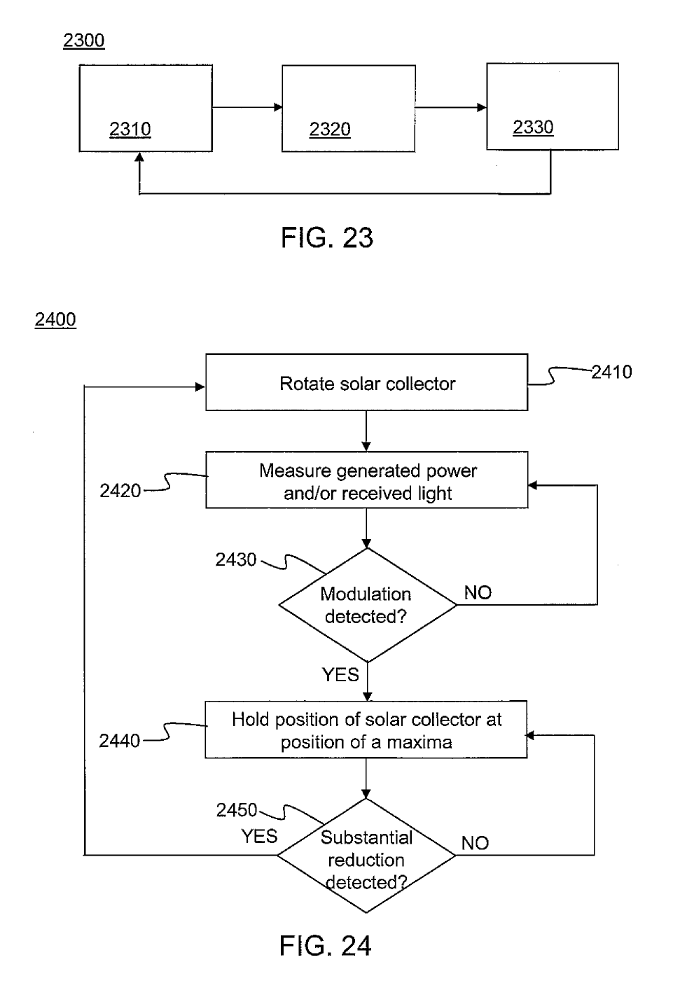

FIG. 23 is a block diagram representing a rotatable three-dimensional solar panel and components 2300 to operate the rotatable three-dimensional solar panel, according to an embodiment. For example, such a rotatable three-dimensional solar panel may be similar to that shown in FIGS. 21 and 22, though claimed subject matter is not limited to any such shapes or configurations. PV cells located on a solar panel represented by block 2310 may generate electrical energy resulting from collected light. (In one implementation, such generated electrical energy may be used to detect and/or measure collected light) A processor represented by block 2320 may comprise a processor or other such computing system or circuitry to receive measurements resulting from light collected from solar panel 2310. Such measurements may comprise a solar signal, for example. Herein, the term “solar signal” may refer to an electrical signal resulting from light energy. For example, a PV cell may generate a solar signal in response to receiving light. Processor 2320 may determine favorable positioning of a rotatable three-dimensional solar panel. For example, with a cloudy sky producing scattered light, relative position (e.g., rotation angle) may not be important in terms of generating power from collecting light—a relatively constant amount a light may reach the three-dimensional solar panel over all angles of rotation. However, with a clear, sunny sky producing direct light, relative position (e.g., rotation angle) may be important in terms of generating power from collecting light—particular angles of rotation of the three-dimensional solar panel may result in generating more power from collecting light than other angles. Accordingly, processor 2320 may determine one or more particular rotation angles that are favorable for generating power from collecting light. As a result of such determination, processor 2320 may instruct block 2330, which may represent a mechanism, such as mechanism 2250 shown in FIG. 22, to stop or lock rotation of a three-dimensional solar panel, to hold a position of a three-dimensional solar panel at a particular, favorable angle. Such a mechanism 2250 may comprise an actuator, a motor, a braking mechanism, and so on. Accordingly, block 2330 may provide mechanical feedback (e.g., braking or release) to solar panels 2310.

FIG. 24 is a flow diagram of a process 2400 to operate a rotatable three-dimensional solar panel, according to another embodiment. In such a process, a rotatable three-dimensional solar panel may rotate in search of a desirable rotation position, which may exist if sky conditions become clear (e.g., resulting in a relatively high proportion of direct light). In other words, the amount of light received may depend on rotation angle during sunny skies. However, while sky conditions are cloudy, rotation of a three-dimensional solar panel need not affect solar generation efficiency since scattered light may reach portions of the three-dimensional solar panel at a substantially constant amount. In other words, the amount of light received may be substantially independent of rotation angle during cloudy skies. At block 2410, a rotatable three-dimensional solar panel may rotate as a result of a motor (which may or may not be energized by at least a portion of electrical energy generated by the rotatable three-dimensional solar panel itself) and/or wind, for example. At block 2420, during rotation, an amount of generated power and/or received light may be measured, resulting in a solar signal, as described above, for example. At diamond 2430, a processor or other electronic circuitry may determine an intensity modulation and/or other characteristics of the solar signal. If no intensity modulation is detected, or if an intensity modulation is relatively small, process 2400 may return to block 2420 where generated power and/or received light may continue to be measured while the rotatable three-dimensional solar panel continues to rotate. In such a case, sky conditions may result in scattered light so that a solar signal may not depend strongly on rotational position of the rotatable three-dimensional solar panel. On the other hand, if intensity modulation is detected, or above a threshold for example, process 2400 may proceed to block 2440 where rotation of the rotatable three-dimensional solar panel may be stopped at a particular rotation angle resulting in favorable solar collection. In such a case, sky conditions may be clear (or have recently cleared) resulting in direct sunlight, wherein a particular rotational position of the rotatable three-dimensional solar panel may produce a relatively large solar signal (and thus a relatively large amount of solar power). For example, modulation maxima of a solar signal may correspond to favorable rotation angles for receiving a relatively large amount of light. In an implementation, the rotatable three-dimensional solar panel may be held in such a rotation position, such as by mechanism 2250 described above, for example. At diamond 2450, possibly during a monitoring process, a determination may be made as to whether a substantial reduction in magnitude of a solar signal produced from the rotatable three-dimensional solar panel has occurred. If not, process 2400 may return to block 2440 where the rotatable three-dimensional solar panel may continue to be held in a rotation position that receives a relatively large amount of light. In such a case, sky conditions may remain unchanged and direct light may still be present. On the other hand, if a substantial reduction in magnitude of a solar signal is detected, then process 2400 may return to block 2410 where the rotatable three-dimensional solar panel may become free to rotate or be rotated. In such a case, sky conditions may have become cloudy, resulting in scattered light. Though a rotational position of a rotatable three-dimensional solar panel may not be important for scattered light, the rotatable three-dimensional solar panel may nevertheless be allowed to rotate in order to “search” for a favorable rotation angle for a next occurrence of clear sky. Thus process 2400 may repeat. Of course, such details of process 2400 are merely examples, and claimed subject matter is not so limited.

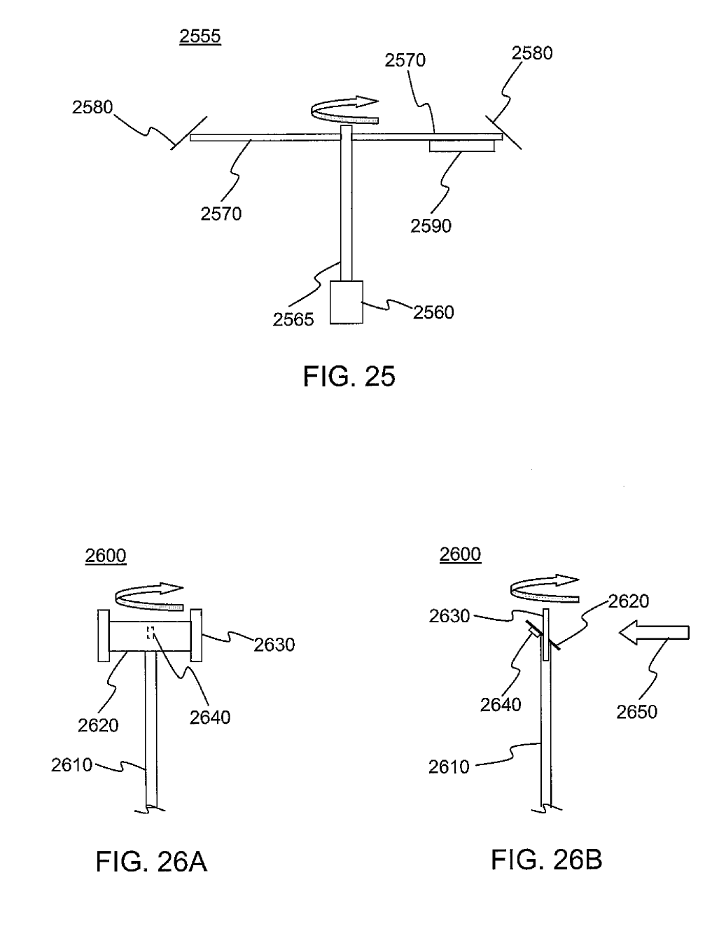

Embodiments described below, and shown in FIGS. 25-30, for example, may include PV cells that may rotate about an axis while generating a solar signal.

Characteristics of such a solar signal may be used to determine sky conditions or environmental conditions in which light received by PV cells travels. Characteristics of such a solar signal may also be used to determine speed of the wind that drives rotation of such PV cells. In a particular application, such embodiments may be used for remote sensing of such conditions, though claimed subject matter is not so limited. For example, a remote weather station employing any of such embodiments may determine or detect sky or weather conditions, as described in detail below.

FIG. 25 is a side view showing a rotatable PV device 2555, according to an embodiment. In particular, a shaft 2565 may be mechanically connected to one or more arms 2570. In one implementation, shaft 2565 may be rigidly connected to one or more arms 2570. In another implementation, one or more arms 2570 may rotate with respect to shaft 2565. One or more solar panels 2580 (e.g., comprising PV cells, photo-detectors, and so on) may be located on a portion of such arms. At least two such solar panels 2580 may simultaneously face different portions of the sky. For example, solar panel 2580 on the right is facing a rightward portion of the sky while solar panel 2580 on the left is facing a leftward portion of the sky. In one implementation, rotatable PV device 2555 may be similar to a weather vane wind gauge. Schematically shown, rotatable PV device 2555 may comprise one or more sails 2590 to produce a torque or rotation of rotatable PV device 2555. Such sails 2590 may be similar to sails 2530 described above. In one particular implementation, while rotation of shaft 2565 may be initiated by a wind force on one or more sails 2590, mechanism 2560 may comprise a motor to rotate shaft 2565 (and thus to rotate PV device 2555, for example) in the absence of wind, for example.

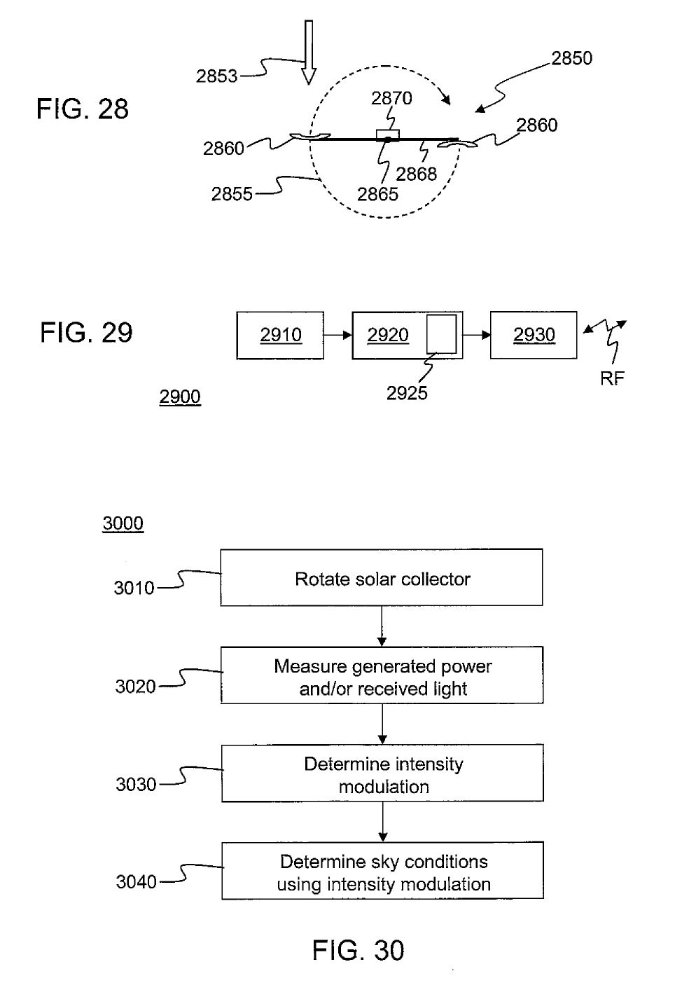

FIG. 26A is a front view showing a rotatable PV cell device 2600 and FIG. 26B is a side view showing the rotatable PV cell, according to an embodiment. As explained above, a rotatable PV cell may be used to detect and/or determine characteristics of the sky and/or weather, whether the sky is sunny, partially cloudy, completely cloudy, foggy, smoky, smoggy, and so on. For example, rotatable PV cell device 2600 may be used to remotely detect or determine such sky characteristics. To illustrate, rotatable PV cell device 2600 may be deployed on ocean buoys, mountainous areas, or other remote areas. A PV cell 2620, which may comprise one or more photovoltaic devices, photodiodes, photo detectors, charge-coupled devices (CCDs) or CCD arrays, solar cells, and so on, may be mounted on a rotatable shaft or other rotatable structure 2610. In an implementation, such sensors need not receive light via a lens or other collimating device, though claimed subject matter is not so limited. In another implementation, PV cell 2620 may be mounted on a bearing, for example, to allow PV cell 2620 to rotate so that structure 2610 need not rotate. PV cell 2620 may or may not be rigidly inclined at an angle from vertical to improve light collecting efficiency. One or more sails 2630 may be mounted to PV cell 2620 and/or mounted to a structure to which PV cell 2620 is also mounted. Such sails may “capture” wind 2650 to produce a torque to rotate rotatable PV cell device 2600, for example. In another implementation, rotatable PV cell device 2600 need not include such sails and rotation of rotatable PV cell device 2600 may instead rely on structural portions of PV cell device 2600 or PV cell 2620 to capture wind and create torque. In yet another implementation (not shown), rotatable PV cell device 2600 need not include such sails and instead rotatable PV cell device 2600 may comprise a motor to rotate rotatable PV cell device 2600 (such as motor 2560 shown in FIG. 25, for example). In a particular embodiment, rotatable PV cell device 2600 may comprise an electronic module 2640 to receive a solar signal from PV cell 2620, and to determine sky/weather conditions based, at least in part, on the solar signal. Such an electronic module may comprise components similar to a weather module shown in FIG. 28 and described below, for example. Electronic module 2640 may wirelessly communicate such a determination to a receiver (not shown) some distance away, for example. In another implementation, electronic module 2640 may receive a solar signal from PV cell 2620, and wirelessly transmit information representing the solar signal to a receiver (not shown) some distance away, for example. Though rotatable PV cell device 2600 is shown to have a particular configuration in FIGS. 26A and 26B, an unlimited number of variations to such a configuration are possible. For example, PV cell 2620 may comprise any number of shapes and sizes, and be located in any number of positions relative to other components of rotatable PV cell device 2600. Of course, claimed subject matter is not limited to any particular configuration.

In another embodiment, a device may be similar to rotatable PV cell device 2600 but need not be rotatable. Such a non-rotatable PV cell device may also be used to detect and/or determine characteristics of the sky and/or weather, whether the sky is sunny, partially cloudy, completely cloudy, foggy, smoky, smoggy, and so on. For example, such a non-rotatable PV cell device may be used to remotely detect or determine such sky characteristics. In detail, such a non-rotatable PV cell device may include a first PV cell facing a first direction to generate a first solar signal and a second PV cell facing a second direction to generate a second solar signal. Differences (e.g., magnitude differences) between first and second solar signals or characteristics of such solar signals may be used to determine sky conditions or environmental conditions in which light received by PV cells travels. Such a determination of sky conditions may be based, at least in part, on the fact that scattered light may reach first and second PV cells in a more uniform fashion compared to the case for direct light, which may reach first and second PV cells at substantially different amounts, as explained above.

Similar to that described for rotatable PV cell device 2600, the non-rotatable PV cell device may comprise an electronic module 2640 to receive a solar signal from the PV cells, and to determine sky/weather conditions based, at least in part, on the solar signals.

Such an electronic module may comprise components similar to a weather module shown in FIG. 28 and described below, for example. Electronic module 2640 may wirelessly communicate such a determination to a receiver (not shown) some distance away, for example. In another implementation, electronic module 2640 may receive a solar signal from the PV cells and wirelessly transmit information representing the solar signal to a receiver (not shown) some distance away, for example.

Such a non-rotatable PV cell device may provide an advantage over rotatable PV cell device 2600 in that the non-rotatable PV cell device need not use moving parts. Benefits of not using moving parts may include, simpler and cheaper construction costs, reduced maintenance, no moving parts to corrode or freeze in remote locations, and wind or a motor need not be relied upon, just to name a few examples. On the other hand, a non-rotatable PV cell device may include disadvantages over rotatable PV cell device 2600. For example, the non-rotatable PV cell device includes more than one PV cell and the multiple PV cells may age or their light-receiving surfaces may become fouled (e.g., by salt spray if deployed on an ocean buoy or by ice, dirt, and so on) by amounts different for one another. Such aging or fouling may lead to reduced solar signal for a given amount of received light (e.g., reduced efficacy). As described below, sky conditions may be determined based, at least in part, on differences between solar signals from the different PV cells. Thus, if a first PV cell becomes fouled more so than a second PV cell, then a difference between solar signals of the first and second PV cells may be attributed to effects other than sky conditions. As a result, inaccurate determinations of sky conditions may result. Of course, such characteristics, benefits, and disadvantages of a non-rotatable PV cell device are merely examples, and claimed subject matter is not so limited.

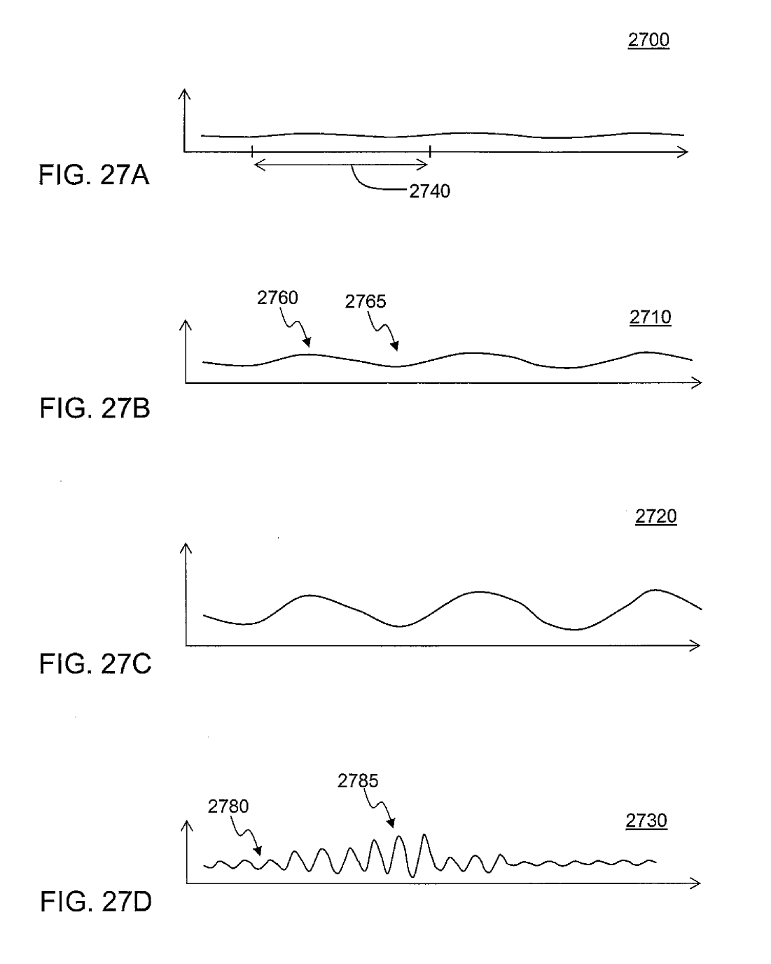

FIGS. 27A-27D show example solar signals as a function of time, according to an embodiment. Horizontal axes may represent time while vertical axes may represent relative magnitude. Plots 2700, 2710, 2720, and 2730 may represent measurements of electrical power and/or energy generated as a result of light collected by a rotatable three-dimensional solar panel or PV cell, for example. Such measurements may comprise a digital and/or analog electronic signal representing intensity (or power) of collected light as a function of time. In the case of a rotating (via wind or motor, for example) three-dimensional solar panel or PV cell, such measurements may comprise a modulating (e.g., involving a sinusoidal or other time-varying function) signal. Period 2740 may represent a complete rotation of a rotating three-dimensional solar panel or PV cell. For example, a modulation, or degree thereof, may comprise a difference between relative maxima 2760 and relative minima 2765, shown in FIG. 27B. Herein, such a signal, or a portion thereof, may be called a solar signal. Plot 2700 comprises a solar signal having a relatively small (or no) modulation. Plot 2710 comprises a solar signal having a relatively moderate modulation. Plot 2720 comprises a solar signal having a relatively large modulation. Plot 2730 comprises a solar signal having a range of relatively small to large modulation (a time scale of plot 2730 may be different from that of plots 2700, 2710, and 2720). As discussed above, an amount of modulation of a solar signal may correspond to a degree that light collected by a rotating three-dimensional solar panel or PV cell is scattered and/or collimated. For example, in terms of electrical generation or solar collection efficiency, orientation of a three-dimensional solar panel or PV cell may be relatively unimportant for scattered light (e.g., produced by clouds), but may be relatively important for direct (e.g., collimated) sunlight. Thus, as a three-dimensional solar panel or PV cell rotates (or engages in other motion which need not be rotational), electrical generation or solar collection efficiency, which may be represented by a solar signal, may modulate with an intensity that may correspond to sky/weather conditions (e.g., that produce various proportions of scattered and/or direct sunlight). For example, plot 2700, having a relatively small modulation, may comprise a solar signal representative of cloudy or foggy weather. Plot 2710, having a relatively moderate modulation, may comprise a solar signal representative of relatively light cloud cover. Plot 2720, having a relatively large modulation, may comprise a solar signal representative of sunny skies. In the example of FIG. 27D, plot 2730 may comprise a solar signal representative of partly cloudy or partly sunny skies. In such a case, relative time spans of particular modulation intensities may represent a degree of proportion of clouds to clear sky. For example, a sky area may comprise 30% clouds and 70% clear sky. Accordingly, plot 2730 may comprise roughly 30% relatively low-modulation portions 2780 (e.g., resulting from scattered light of clouds) while plot 2730 may comprise roughly 70% relatively high-modulation portions 2785 (e.g., resulting from direct light of clear sky). Thus characteristics of solar signals, such as included in plot 2730, may be used to determine particular sky/weather conditions, cloud type, and so on. For example, cloud types may include cumulus, stratus, cirrus, and so on.

In an implementation, solar signals, such as those represented by plots 2700, 2710, 2720, or 2730, may be analyzed by electronic circuitry. For example, analog or digital electronic components may be used to measure differences between relative maxima 2760 and relative minima 2765 and to consequently determine sky conditions. Such a determination may be stored in a memory or reported to a remote location, or displayed on a display device, for example.

In another implementation, solar signals, such as those represented by plots 2700, 2710, 2720, or 2730, may be analyzed by an application executed by a processing entity. For example, differences between relative maxima 2760 and relative minima 2765 may be compared to look-up tables stored in a memory accessible by the processing entity. Such look-up tables may comprise data that represent various sky conditions at different geographic locations (e.g., latitude). Such data may be based, at least in part, on data collected in such locations or experimental or interpolated values of solar signals produced by a priori-known sky conditions, for example. Other characteristics of such solar signals, such a time, may be considered by an executable application to determine sky conditions. For example, plot 2730 may represent a solar signal resulting from particular sky conditions. Variations of intensity and spans of time for such variations of intensity may be considered for determining sky conditions. For example, a solar signal having an averaged intensity that is relatively high for a few minutes followed by an averaged intensity that is relatively low for a few minutes may indicate presence of cumulus clouds. Such an executable application may also consider conditions in addition to characteristics of a solar signal to determine sky conditions. For example, such additional conditions may include current or historical wind speed or direction, current or historical precipitation rate, current or historical temperature, current or historical barometric pressure, current or historical dew-point, current or historical observed weather patterns, and so on.

FIG. 28 is a top view showing a cup-type anemometer 2850 that includes a weather module 2870, according to an embodiment. A cup-type anemometer may be useful in an implementation of the weather module because it rotates in a wind with substantially regular (over relatively short periods of time, such as seconds, for example) periodicity. Any such rotating device, such as arms of a radar unit, fan blades, and so on, may also be useful if a substantial portion of the sky is visible from the device. Such a weather module may comprise a compact, self-contained version of a structure similar to rotatable solar panel 2600 described above, for example. For example, such a weather module may be used to determine particular sky/weather conditions, cloud type, and so on. To perform such a determination of weather conditions, weather module 2870 may comprise one or more PV cells, photodiodes, or photosensors, for example, to measure a solar signal and to face different portions of the sky as an orientation of the weather module 2870 changes. As discussed above, such a solar signal may be used to determine characteristics of received light (e.g., collimated, scattered, relative intensity, and so on). Further, weather module 2870 may comprise a self-contained module that may be attached to an existing cup-type anemometer or object that is capable of rotating or changing orientation with respect to the sky. For example, a cup-type anemometer is capable of spinning or rotating in a wind. In another example, a weather vane is capable of rotating or changing orientation with respect to the sky as a direction of wind changes. Accordingly, weather module 2870, attached to any such object, may also rotate or change orientation.

Weather module 2870 comprising such a self-contained module may include a wireless transmitter to transmit information regarding measured solar signal, weather/sky conditions, and/or other related information to a receiver, for example. Such a receiver may be located any distance away from weather module 2870, such as on an orbiting satellite, on a rigid (with respect to earth) portion of the cup-type anemometer 2850, or on land nearby, for example. Weather module 2870 may provide benefits such as remote sensing of weather conditions, self-contained to wirelessly provide such weather conditions, convenient placement onto existing objects, and so on, for example.

In one implementation, a cup-type anemometer may comprise one or more arms 2868 rotationally supported by an axial support 2865. One or more sails or wind cups 2860 may be located on arms 2868. Such wind cups may comprise any of a variety of shapes and sizes to capture wind 2853 to apply torque to arms 2868, for example. Weather module 2870 may be attached to a rotating portion of cup-type anemometer 2850. For example, weather module 2870 may be connected to a portion of arms 2868 and/or wind cups 2860. Locating weather module 2870 relatively close to a rotational axis of arms 2868 may be favorable in terms of maintaining a balanced configuration (e.g., to reduce tendency to wobble during rotation). Any of a number of techniques for attaching weather module 2870 to cup-type anemometer 2850 may be used, such as magnetic attachment, mechanical attachment, and so on.

As discussed above, weather module 2870 may determine proportion of scattered light to direct light, thereby allowing a determination of sky conditions. In the case of a rotating (e.g., or other substantially periodic motion) weather module, such determinations may be similar to that described above for FIGS. 25 through 27D. In the case of a (non-rotating) weather module that may change its orientation from time to time, such determinations may be similar to that described above for FIGS. 25 through 27D by using additional information from a timing module and/or an orientation sensor, which may provide information to allow correlation between sensor orientation and time. For example, such information may lead to a solar signal as a function of time and portion of the sky. In other words, such information may lead to knowledge of the time that a solar signal was measured and what portion of the sky was measured at that time. A processor, for example, may use such information to determine proportion of scattered light to direct light, thereby allowing a determination of sky conditions. Thus, in an implementation, weather module 2870 may include a timing module to allow measurements of a solar signal in a time domain. Weather module 2870 may also include an orientation sensor to allow measurements of orientation of weather module 2870. Such an orientation sensor may comprise a compass, a gyroscope, GPS, a gravitometer, and so on. As mentioned above, a processor included in weather module 2870 may use a solar signal in a time domain and/or orientation of the weather module to determine proportion of scattered light to direct light, thereby allowing a determination of sky conditions.

In one particular implementation, wind speed measured by anemometer 2850 (e.g., a rotation rate) may be determined based, at least in part, on the frequency of modulation of solar signals generated by PV cells, for example, located on weather module 2870. Thus, a rotation rate of the anemometer may be determined without using mechanical or electro-magnetic techniques, which may introduce undesirable mechanical or electro-magnetic friction or drag. Such drag may introduce errors in measuring anemometer rotation rate and thus may introduce errors in wind speed measurements. Of course, such details of a weather module are merely examples, and claimed subject matter is not so limited.

FIG. 29 is a block diagram of components that may be included in a weather module 2900, which may be similar to that of module 2870, according to an embodiment. Such components may be included in another type of module to operate a rotatable three-dimensional solar panel, according to other embodiments. For example, such a rotatable three-dimensional solar panel or PV cells may be similar to that shown in FIGS. 21, 22, 25, 26A, and 26B, though claimed subject matter is not limited to any such shapes or configurations. Block 2910 may comprise sensors to detect and/or measure collected light, electrical energy resulting from such collected light, and so on. Such sensors may comprise one of or a combination of one or more photosensors, photocells, photodiodes, solar panels, solar cells, PV cells, CCDs or CCD arrays, volt or current meters, electrical measurement circuits, and so on. Such a listing is not intended to be complete or exhaustive, but instead is merely intended to provide an idea of such components that may be involved in detection and/or measuring in embodiments described herein. Block 2920 may comprise a processor or other such computing system or circuitry to receive measurements or solar signal resulting from collected light. Such measurements may comprise a digital and/or analog signal representing intensity (or power) of collected light as a function of time. In the case of a rotating (via wind or motor, for example) three-dimensional solar panel or photosensor of a weather module, such measurements may comprise a modulating (e.g., involving a sinusoidal or other time-varying function) signal. As discussed above, such a signal, or a portion thereof, may be called a solar signal. For example, if a rotatable three-dimensional solar panel or photosensor of a weather module is receiving scattered light (e.g., on a cloudy day), such a solar signal may comprise a relatively small amount of modulation (e.g., see FIG. 27A), since orientation of solar panels in scattered light is relatively unimportant. On the other hand, if a rotatable three-dimensional solar panel is receiving collimated light (e.g., on a clear and sunny day), such a solar signal may comprise a relatively large amount of modulation (e.g., see FIG. 27C), since orientation of solar panels in collimated light is relatively important. Processor 2920, for example, may detect and/or quantify such a modulation included in solar signals resulting from measurements provided by sensors 2910. In an implementation, such sensors need not receive light via a lens or other collimating device, though claimed subject matter is not so limited. Also, processor 2920 may detect and/or quantify time variation of modulation included in solar signals such as that shown in FIG. 27D, for example.

In one embodiment, processor 2920 may access a memory 2925 that maintains stored information regarding solar intensity at different locations on earth (e.g., latitude) at different times of day at different times of year for different weather conditions. For example, such information may comprise archive information associated with weather or solar gain as a function of location. Stored information may include, for example, historical wind speed, precipitation rate, temperature, barometric pressure, dew-point, and so on. Also, processor 2920 may have access to a clock to know time of day or time of year, for example. Using such a clock and/or database of information, processor 2920 may determine sky and/or weather conditions by comparing information in such a database to measurements received from sensors 2910. Time of day and/or time of year may affect intensity of a solar signal. For example, and average value of a modulating solar signal may depend, at least in part, on time of day, time of year, latitude, and degree of cloudiness. Thus, such an average value may be used to determine a degree of cloudiness (e.g., thick or heavy clouds, light clouds, and so on). In one implementation, a database may also include information produced from calibration. For example, in response to sensors 2910 providing a particular measurement to processor 2920 (or a memory or buffer from which processor 2920 may read), a user may provide sky/weather condition information (e.g., sky is cloudy, slight drizzle) corresponding to the time that the particular measurement was performed by sensors 2910. Such calibration may allow processor 2920 to improve its ability to associate sensor measurements (and thus solar signals) with sky/weather conditions. Accordingly, processor 2920 may provide sky/weather conditions to block 2930, which may comprise output to a user interface or memory. In one implementation, block 2930 may comprise a radio-frequency (RF) transmitter to wirelessly transmit information regarding sky conditions to a land-based or satellite-based receiver.

In one implementation, weather module 2900 may comprise a CCD array to measure images. In such a case, specialized software may be used to analyze images for presence of the sun, and/or an amount by which the sun may be obscured by clouds, haze, or fog, for example. Such software may be executed by a processor on board weather module 2900, as represented by block 2910, or by a processor located remotely from the weather module.

In one implementation, weather module 2900 may operate using electrical power generated from PV cells included in the weather module. For example, electronic circuitry may analyze such generated electrical power to determine its modulation or other characteristics while such generated electrical power may be used to power components of weather module 2900 and/or charge battery cells of the weather module. In a particular implementation, a system (e.g., weather module 2900) may comprise a PV cell, a processor to receive electrical signals from the PV cell, wherein the processor may be capable of determining modulation of the received electrical signals. Such a processor may generate information representative of weather conditions, wherein such information is based, at least in part, on the modulation. The system may further comprise an input/output (I/O) port to transmit such information wirelessly to a location other than that of the system, for example. Such an I/O port may be capable of receiving instructions from such a location other than that of the system, such as a satellite or land- or ship-based station. For example, such instructions may comprise commands to operate the system or update archive information associated with weather or solar gain as a function of location. As mentioned above, such information may be stored in a memory of the system. Commands to operate the system may include power off, power on, change from one algorithm that determines weather conditions to another such algorithm, boost or lower transmission power, request information regarding parameters of the system (e.g., battery power, PV cell voltage/current generation, and so on), or other commands concerned with operating a weather module that may be remotely located. Such a system may be capable of operating using an operating system that may be remotely updated or changed with instructions received via the I/O port. Such a system may be addressable among a plurality of such systems (e.g., respectively located in different locations) by including an identification that is unique among the plurality of systems.

In one example, rotatable three-dimensional solar panel 2555 or weather module 2870 located in Newport, Oreg., at 9:00 AM, on January 17 may produce a particular solar signal having a relative large modulation and relatively small average intensity (e.g., in terms of expected clear-sky intensity for Newport, Oreg., at 9:00 AM, on October 22). Processor 2920 may compare such features of the particular solar signal with information stored in memory 2925. In one implementation, such information may be used to calculate expected clear-sky intensity for Newport, Oreg., at 9:00 AM, on January 17. In another implementation, such information may comprise values of expected clear-sky intensity for Newport, Oreg., at 9:00 AM, on January 17. In either case, such features, for example, may include intensity, magnitude, modulation (e.g., magnitude difference between maxima and minima of a modulating signal), time span of particular portions of the solar signal, and so on. Accordingly, processor 2920 may determine that the particular measured solar signal represents a light haze, since the solar signal comprised a relative large modulation (e.g., indicating relatively direct sunlight and relatively small amount of scattered light) and relatively small average intensity (indicating a presence of some vapor in the sky to reduce the solar signal intensity to below what is otherwise expected for Newport, Oreg., at 9:00 AM, on January 17). RF transmitter 2930 may transmit information regarding sky conditions to a land-based or satellite-based station (not shown).

In another example, rotatable three-dimensional solar panel 2555 or weather module 2870 located in Newport, Oreg., at 11:30 AM, on March 28 may produce a particular solar signal having a relative small modulation and relatively small average intensity (e.g., in terms of expected clear-sky intensity for Newport, Oreg., at 11:30 AM, on March 28). Accordingly, processor 2920 may determine that the particular measured solar signal represents a cloudy sky, since the solar signal comprised a relative small modulation (e.g., indicating a relatively high degree of scattered light) and relatively small average intensity (indicating relatively thick clouds to reduce the solar signal intensity to below what is otherwise expected for Newport, Oreg., at 11:30 AM, on March 28).

FIG. 30 is a flow diagram of a process 3000 to operate a rotatable three-dimensional solar panel, PV cell, or weather module, according to an embodiment. At block 3010, a rotatable three-dimensional solar panel, PV cell, or weather module may rotate as a result of a motor (which may or may not be energized by at least a portion of electrical energy generated by the rotatable three-dimensional solar panel itself) and/or wind, for example. At block 3020, an amount of generated power and/or received light may be measured, resulting in a solar signal, as described above, for example. At block 3030, a processor or other electronic circuitry may determine intensity modulation and/or other characteristics of the solar signal. At block 3040, such intensity modulation and/or other characteristics of the solar signal may be used to determine sky/weather conditions. Of course, such details of process 3000 are merely examples, and claimed subject matter is not so limited.

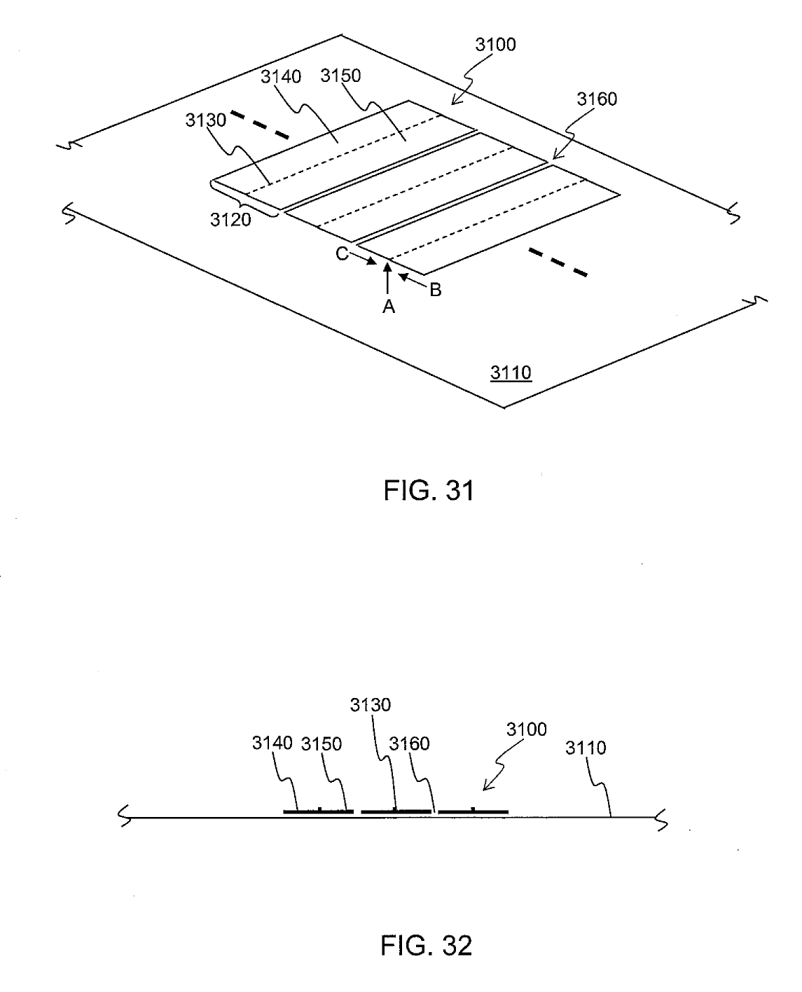

Embodiments described herein, in FIGS. 31-42, for example, are directed to solar panels that may change shape or configuration. Such solar panels may flatten or fold, for example. An ability of a solar panel to change shape or configuration may provide techniques to determine whether light incident upon the solar panel is predominantly collimated or scattered. Such a determination may lead to a number of implementations. In one implementation, for example, such a solar panel may be used to detect and/or determine characteristics of the sky and/or weather, whether the sky is sunny, partially cloudy, completely cloudy, foggy, smoky, smoggy, and so on. In another implementation, for example, a solar panel able to change shape or configuration may be used to generate electrical energy at a desirable (e.g., optimal) efficiency (e.g., light gathering efficiency) by determining whether incident light is predominantly collimated or scattered. In such an implementation, as explained in detail below, a solar panel may change its shape or configuration on-the-fly to correspond to a present type of incident light.

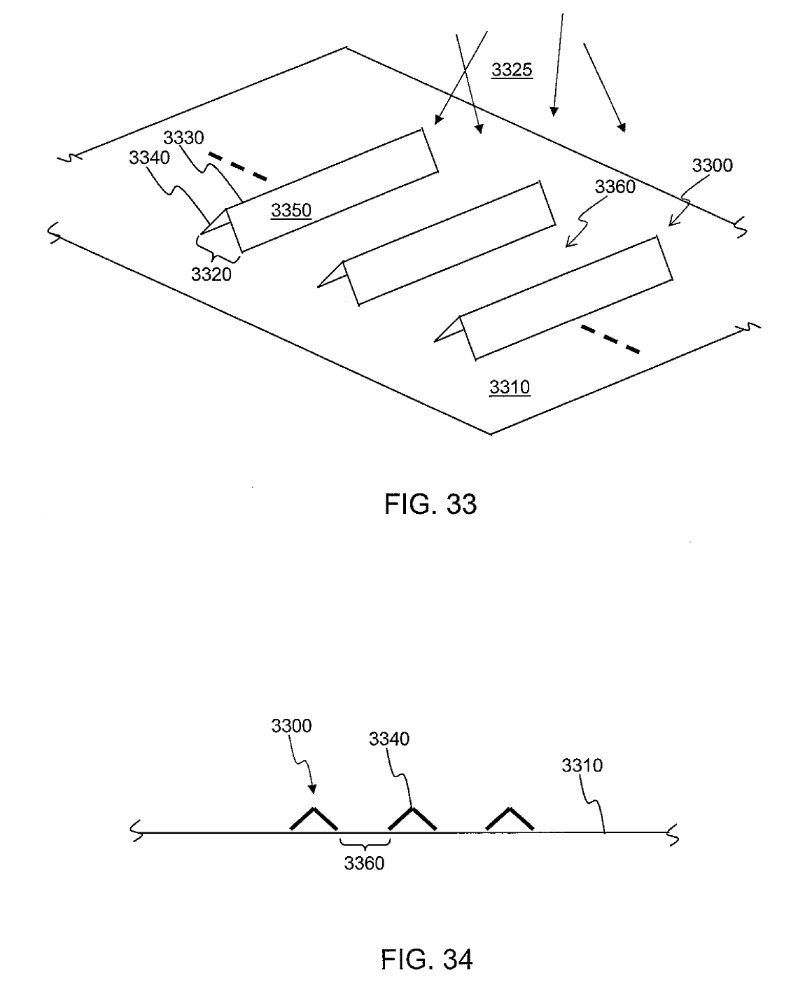

FIG. 31 is a perspective view showing shape-changing three-dimensional solar panels 3100 and FIG. 32 is a side view showing the shape-changing three-dimensional solar panels, according to an embodiment. Such panels, for example, may be located on a surface 3110 such as a rooftop, ground, deck, floating object, and so on. Solar panels 3100 may comprise a substantially flat configuration, as shown in FIG. 31, for example, or be changed to a folded configuration, as shown in FIG. 33, for example. In detail, such folding may be performed as fold line 3130 lifts in a direction indicated by arrow “A” while panel portions 3140 and/or 3150 move in a direction indicated by arrows “B” and “C”. Such folding may be performed or initiated by a motor (not shown) applying a force on a portion of one or more solar panels 3100, for example. A substantially flat configuration of solar panels 3100 may occupy a length 3120 of surface 3110 (compare with lesser length 3320 for a folded solar panel shown in FIG. 33, for example). In such a configuration, solar panels 3100 may receive direct light in a relatively efficient manner. On the other hand, a folded configuration of solar panels 3100 may receive scattered light in a relatively efficient manner while occupying a length less than that of length 3120. Accordingly, a folded configuration of solar panels 3100 may lead to additional area of surface 3110 that may be occupied by additional solar panels to increase solar collection during scattered light conditions (e.g., gray skies), as explained below. For example, adjacent solar panels 3100 may be spaced apart by an area 3160, which may be increased (to additional area 3360, shown in FIG. 33) upon folding of solar panels 3100.

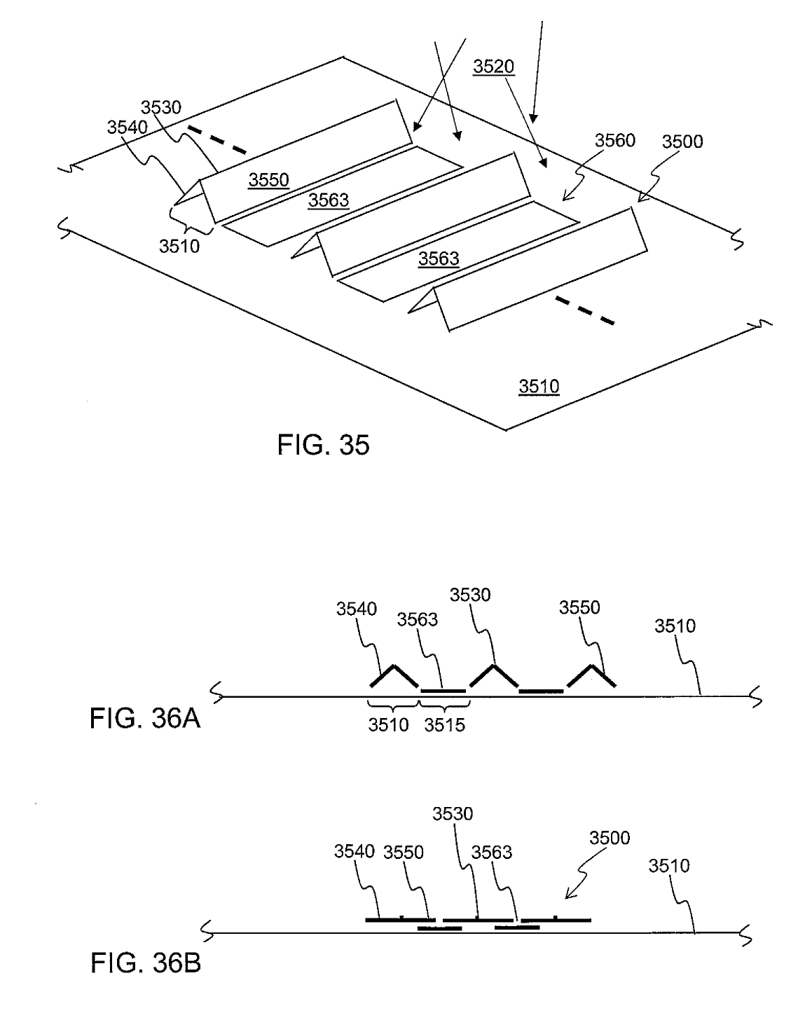

FIG. 33 is a perspective view showing three-dimensional solar panels 3300 and FIG. 34 is a side view showing the three-dimensional solar panels, according to another embodiment. Folded solar panels 3300 may be folded at a fold line 3330, for example. The situation depicted in FIG. 33 may occur while solar panels 3100 in FIG. 31 are in a folded configuration, for example. Thus, as mentioned above, such a folded configuration may result in additional area 3360 of surface 3310 that may be used for additional solar panels, such as additional solar panels 3563 shown in FIG. 35, for example. Such a folded configuration of solar panels 3300 may be relatively efficient at collecting scattered light 3325 for generating electrical energy, as discussed above. For example, scattered light 3325 may impinge on portion 3340 and portion 3350 of folded solar panel 3300 at substantially equal amounts. Since such a folded solar panel 3300 may occupy an area less than that of flattened solar panel 3100, additional area 3360 may be available for solar panels to help increase solar collection during gray skies.

In one particular embodiment, three-dimensional solar panels 3300 may comprise portion 3340 and portion 3350 that are substantially rigid with respect to each other. In such an embodiment, three-dimensional solar panels 3300 need not be capable of shape-changing on-the-fly. Instead, one or more such rigid three-dimensional solar panels 3300 may be adjacently placed on a surface (e.g., rooftop, ground, or other surface) in a configuration shown in FIG. 33 (e.g., folded at a particular angle), with or without an area 3360. In an implementation, however, such rigid three-dimensional solar panels 3300 may be packaged and/or shipped in a flattened or tightly folded configuration, wherein they may be folded or stretched to install in the “field”.

FIG. 35 is a perspective view showing a shape-changing three-dimensional solar panel configuration and FIGS. 36A and 36B are side views showing the shape-changing three-dimensional solar panel configuration, according to an embodiment. The situation depicted in FIG. 35 may be similar to that shown in FIG. 33, wherein additional area 3360 is occupied by solar panel 3563. Thus, as mentioned above, such a folded configuration of solar panels 3500 may result in additional area 3560 of surface 3510 that may be used for additional solar panels 3563, for example. FIG. 36B shows the shape-changing three-dimensional solar panel configuration of FIG. 36A in a flattened configuration. In one implementation, additional solar panels 3563 may be substantially covered by flattened solar panels 3500. In a process of folding solar panels 3500, such as during scattered light conditions, additional solar panels 3563 may become exposed to the scattered light, thus contributing to solar generation during cloudy skies. In one implementation, additional solar panels 3563 need not be flat, but may comprise any of a number of possible shapes or configurations. For example, additional solar panels 3563 may comprise one or more folded and/or curved surfaces.

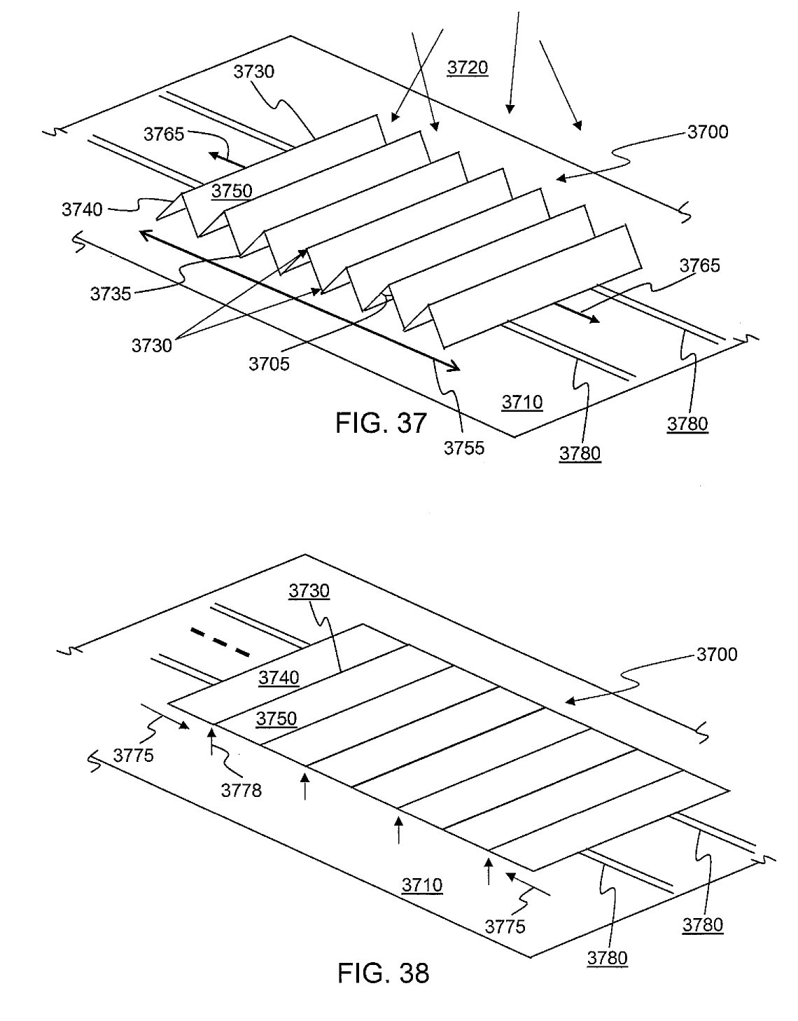

At least portions of the following descriptions of embodiments shown in FIGS. 37-42 may be applicable to embodiments described for FIGS. 31-36. Such embodiments may be directed to foldable solar panels that may comprise any of a number of possible configurations. For example, a plurality of such foldable solar panels may be connected to one another in any of a number of ways, and details included herein are not intended to be exhaustive and are not intended to limit claimed subject matter. Herein, such details described for configurations of some embodiments may be applied to other embodiments where applicable, unless otherwise noted.

FIG. 37 is a perspective view showing a foldable three-dimensional solar panel 3700 and FIG. 38 is a perspective view showing a flattened three-dimensional solar panel 3700, according to an embodiment. Solar panel 3700 may be folded, unfolded, stretched, compressed, and so on, in an accordion fashion, for example. Solar panel 3700, which may comprise one or more individual solar panels 3740 and 3750, may be configured in a folded shape to maintain its overall surface area while decreasing its footprint area, that is, the coverage area on the earth surface or a rooftop for example. Such a decreased footprint area may be used for additional solar panels, for example. Though surface area of solar panel 3700 may be so maintained from a flattened to a folded configuration, geometrical positioning of surfaces of individual solar panels 3740 and 3750 of the folded solar panel 3700 may geometrically hinder sunlight from reaching these surfaces. However, scattered light 3720 need not be so hindered since such light may arrive from substantially all skyward directions, whereas non-scattered light may come from one direction, the sun, for example. Cloudy skies may produce such scattered sunlight.

An angle 3705 between solar panels 3740 and 3750 may be determined to optimize solar gain. For example, if angle 3705 is too small (e.g., sharp folding), then solar panel 3700 may occupy a desirably small footprint area but solar radiation may not reach lower portions of solar panel 3700 (e.g., near apex 3735). On the other hand, if angle 3705 is too large (e.g., an almost flattened configuration), solar radiation may reach all portions of solar panel 3700 but footprint area may be undesirably large. To provide an example, if angle 3705 comprises a value of 90 degrees, a footprint area of folded solar panels 3700 may be 30% less than that of flattened solar panels 3700. In another example, if angle 3705 comprises a value of 120 degrees, a footprint area of folded solar panels 3700 may be 50% less than that of flattened solar panels 3700. Of course, such angles are merely examples, and claimed subject matter is not limited in this respect.

As shown, individual solar panels 3740 and 3750 may be placed next to one or more similarly solar panels. Individual solar panels 3740 and 3750 may be coupled to one another electrically and/or mechanically, or such panels may be configured so that their respective electrical connections are separate. In a particular embodiment, one or more of individual solar panels 3740 and 3750 may be connected to one another along their respective edges. In another particular embodiment, individual solar panels 3740 and 3750 may be spaced apart and/or not connected to one another, such as in FIG. 33 for example. In an embodiment, individual solar panels 3740 and/or 3750 may comprise a single, or one or more solar panels or photovoltaic cells.

In one implementation, solar panel 3700 may be placed on one or more rails or guides 3780. A motor (not shown), for example, may apply a force 3765 substantially in a direction of rails or guides 3780 to fold or flatten solar panel 3700. One or more such forces may be applied at any one or more portions of solar panel 3700. As solar panels are flattened from a folded configuration, solar panel 3700 may be stretched or lengthened as indicated by arrow 3755 for example. On the other hand, as solar panels are folded from a flattened configuration, solar panel 3700 may be compressed or shortened as indicated by arrows 3775, for example. As solar panel 3700 is folding, fold lines 3730 may raise upward, as indicated by arrows 3778, for example. In another implementation, such fold lines may lower downward, and claimed subject matter is not limited to either such case. Solar panel 3700 and/or rails or guides 3780 may be placed on a surface 3710, which may comprise a rooftop, ground, wall, or any other object, for example.

In one particular embodiment, solar panel 3700 may comprise portion 3740 and portion 3750 that are substantially rigid with respect to one another. In such an embodiment, three-dimensional solar panel 3700 need not be capable of shape-changing on-the-fly. Instead, such a rigid three-dimensional solar panel 3700 may be placed on a surface (e.g., rooftop, ground, or other surface) in a configuration shown in FIG. 37 (e.g., folded at a particular angle). In an implementation, however, such a rigid three-dimensional solar panel 3700 may be packaged and/or shipped in a flattened or tightly folded configuration, wherein such a solar panel may be folded or stretched to install in the “field”, for example. Such folding or stretching may be similar to an accordion-type of action. Similar implementations are discussed in relation to FIG. 47 below.

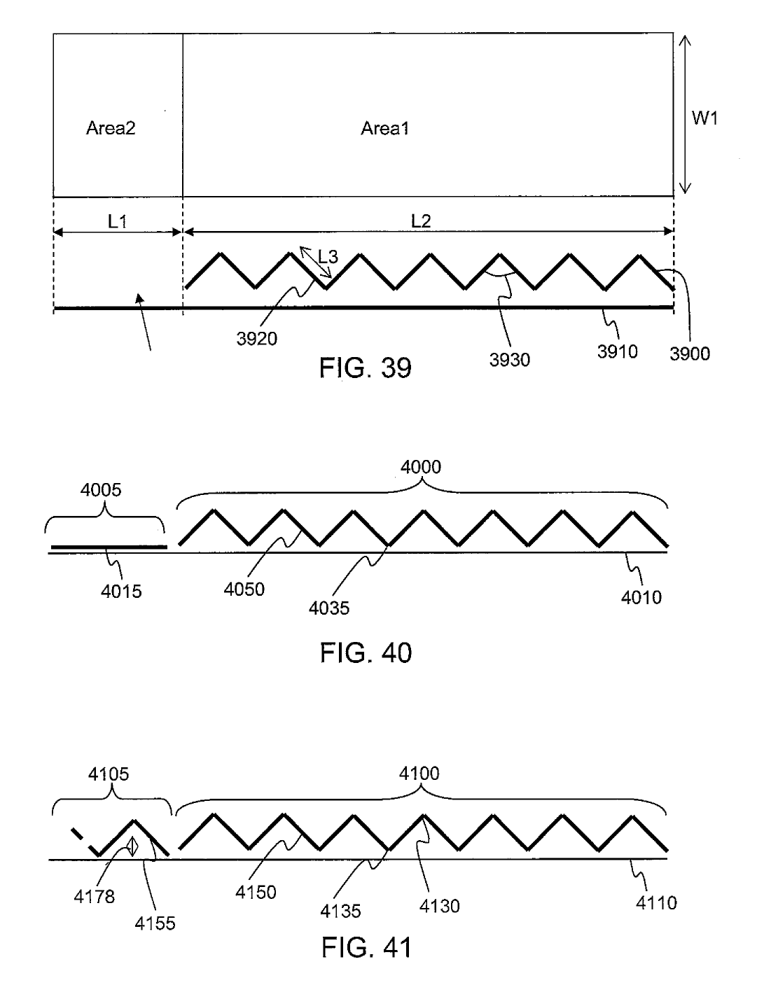

FIG. 39 is a side view showing a shape-changing three-dimensional solar panel and associated dimensions, according to an embodiment. Such a shape-changing three-dimensional solar panel may be similar to that shown in FIGS. 37 and 38, for example. Such a shape-changing three-dimensional solar panel may comprise a folded configuration 3900 or a flattened configuration 3910. As depicted in FIG. 39, folded configuration 3900 may have a length L1 less than that of flattened configuration 3910. For a numerical example, if individual panels 3920 have a length L3 of 1.0 meters, angle 3930 between individual panels 3920 is 90 degrees, and shape-changing three-dimensional solar panel comprises 14 individual panels 3920, then the length L2 of folded configuration 3900 may be

L2=14*(1.0 meters*cosine(90/2))=9.9 meters.

In contrast, the length (L1+L2) of flattened configuration 3910 may be

(L1+L2)=14*1.0 meters=14.0 meters.

Thus, in this example, folded configuration 3900 may have a length 4.1 meters less than that of flattened configuration 3910. Also depicted in FIG. 39, an Area1 in a top view of folded configuration 3900 may be less than that of flattened configuration 3910 by an amount Area2. If, for the numerical example above, individual panels 3920 have a width W1 equal to 1.0 meters, then folded configuration 3900 may have an area 4.1 square meters less than that of flattened configuration 3910.

As discussed above for three-dimensional solar panels, folded configuration 3900 may capture scattered light more efficiently than flattened configuration 3910. Shape-changing three-dimensional solar panels may also provide another benefit, as shown in the above numerical example, in that folded configuration 3900 may occupy less area than that of flattened configuration 3910. For example, folded configuration 3900 may have an equal amount of surface area as flattened configuration 3910 but in a substantially less area. Of course, such details of a folded configuration of solar panels are merely examples, and claimed subject matter is not so limited.

FIG. 40 is a side view showing a three-dimensional solar panel, according to an embodiment. FIG. 41 is a side view showing a three-dimensional solar panel, according to another embodiment. Such embodiments may include techniques for utilizing additional area resulting from a three-dimensional solar panel transitioning from a flattened configuration to a folded configuration, as discussed for FIGS. 37-29, for example. In the numerical example above, for instance, transitioning from a flattened configuration 3910 to a folded configuration 3900 resulted in additional area of 4.1 square meters. In FIG. 40, such additional area 4005 may be occupied by an additional solar panel 4015 (which may or may not be substantially flat, for example). Such an additional solar panel 4015 may be located on a surface (e.g., a rooftop, ground, or other surface) adjacent to a folded three-dimensional solar panel 4000. In one implementation, solar panel 4015 may be covered by three-dimensional solar panel 4000 if three-dimensional solar panel 4000 transitioning from a folded configuration to a flattened configuration. For example, one or more individual panels 4050 may overlay solar panel 4015. Solar panel 4015 may be positioned relative to three-dimensional solar panel 4000 to avoid mechanical conflict if three-dimensional solar panel 4000 transitions between a folded configuration and a flattened configuration. For example, solar panel 4015 may be positioned below fold portions 4035 of three-dimensional solar panel 4000.

In another embodiment, shown in FIG. 41, additional solar panel 4105, comprising individual panels 4155, may be in a substantially flattened configuration if three-dimensional solar panel 4100 is also in a flattened configuration. However, as three-dimensional solar panel 4100 transitions from a flattened configuration to a folded configuration, solar panel 4105 may also transition from a flattened configuration to a folded configuration. For example, additional solar panel 4105 may comprise one or more springs or pistons (not shown) to impart a force on at least a portion of solar panel 4105 to result in a folding motion. Solar panel 4105 may be held in a relatively flattened configuration while covered by at least a portion of three-dimensional solar panel 4100 in a flattened configuration. However, as three-dimensional solar panel 4100 retracts during a transition from a flattened configuration to a folded configuration, portions of solar panel 4105 may move upward, as indicated by arrow 4178, resulting in a folded configuration. As in the case shown in FIG. 40, three-dimensional solar panel 4100 may comprise a plurality of individual panels 4150 including folding portions 4135 or 4130, and may be located on a surface 4110.

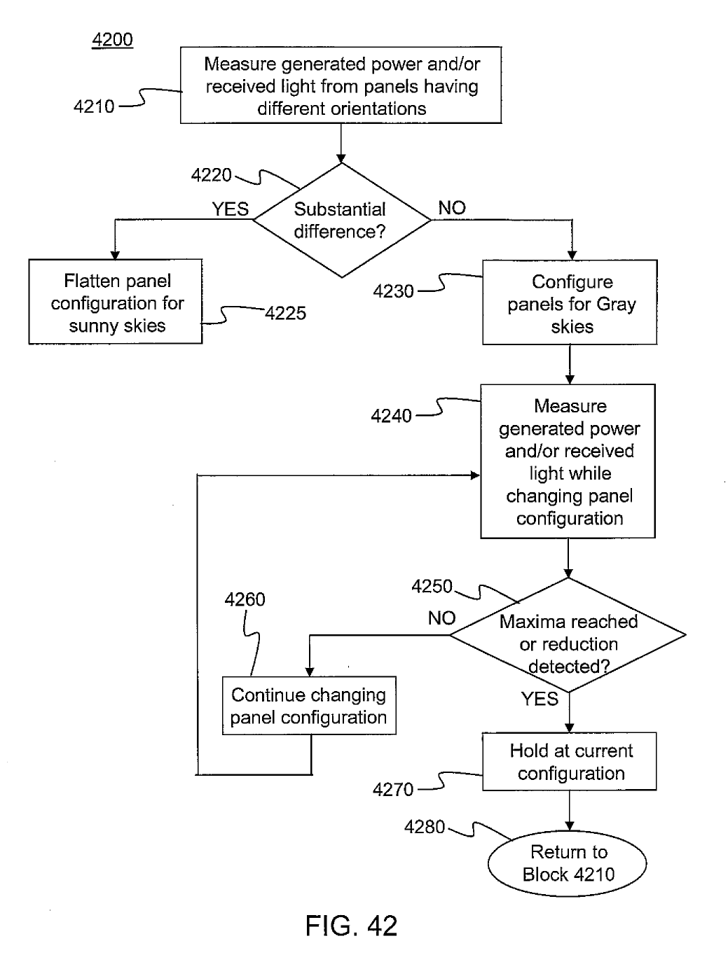

FIG. 42 is a flow diagram of a process 4200 to operate a shape-changing three-dimensional solar panel, according to an embodiment. At block 4210, generated electrical power and/or light received from panels may be measured for two or more different orientations of the panels. In one example, first measurements may be performed for panels being in a first orientation, and second measurements may be performed for panels being in a second orientation. In another example, first measurements may be performed by panel 3740 facing one direction, and second measurements may be performed by panel 3750 facing another direction, referring to FIG. 37. Such panels may be similar to any one or a combination of panels shown in FIGS. 2-6, 8-10, 21-22, and 31-41, for example. Such measurements may include measured power, voltage, current, charge, and/or other quantity representing light collected by panels, for example. At diamond 4220, a determination may be made as to whether there is a substantial difference between first and second measurements. For example, if such a difference is beyond a threshold value then process 4200 may proceed to block 4225, where the panel(s) may be configured for relatively sunny skies. For an example, solar panels 650, 660, 670, and 680 shown in FIG. 6B may be flattened to expose a relatively large portion of panel area to direct light of the sun. For another example, three-dimensional solar panels 3300 shown in FIG. 33 may be flattened to a configuration shown in FIG. 31 to expose a relatively large portion of panel area to direct light of the sun. For yet another example, foldable three-dimensional solar panel 3700 may be flattened to a configuration shown in FIG. 38 to expose a relatively large portion of panel area to direct light of the sun. On the other hand, if such a difference determined at diamond 4220 is less than a threshold value then process 4200 may proceed to block 4230, where panels may be configured for gray skies (e.g., scattered light). For an example, solar panels 610, 620, 630, and 640 shown in FIG. 6A may be folded or arranged to reduce footprint area while maintaining panel area to receive scattered light. For another example, three-dimensional solar panels 3100 shown in FIG. 31 may be folded to a configuration similar to that shown in FIG. 33 to receive scattered light while resulting in additional area 3360 that may be used for additional solar panels to increase light gathering during cloudy skies. For yet another example, three-dimensional solar panel 3700 may be folded to a configuration shown in FIG. 37 to receive scattered light while resulting in additional area 4005 (FIG. 40) or Area2 (FIG. 39) that may be used for additional solar panels 4015 or 4155 to increase light gathering during cloudy skies.

As described above, solar panels may be in a substantially flat configuration for direct light or a folded configuration for scattered light. In an implementation, a desirable degree of fold, which may be quantified by angle 3930 in FIG. 39, for example, may be determined. Such a desirable degree of fold, or other desirable configuration of solar panels, may comprise a degree of fold or configuration resulting in relatively high light gathering or electrical power-generating performance. For example, for scattered light, if solar panel 3700 is folded too tightly (e.g., a relatively small angle 3705), then even scattered light may find it difficult to reach some portions of solar panel 3700, such as portions at or near apex 3735. However, if solar panel 3700 is folded too little (e.g., a relatively large angle 3930), then additional area 4005 may be less than it otherwise may be. In such a case, foldable solar panel 3700 may be operating at less than optimal efficiency. Accordingly, it may be desirable to determine a degree of fold or configuration resulting in a relatively high light gathering or electrical power-generating performance. Process 4200 may include a process to make such a determination, as follows.

At block 4240, light gathering or electrical power-generating performance may be measured (similar to such measurements performed in block 4210, for example) while solar panels are changing their configuration. Any of a number of techniques for performing such measurements while adjusting configuration of panels may be used. For example, in a particular implementation, such measurements may be performed at various degrees of configuration change. For example, solar panels may fold by a particular amount, then hold their position while measurements are performed, then resume folding up to another particular amount, then hold while further measurements are performed, then resume folding, and so on. Such a technique may be similar to that explained below for Table 1, for example. Process 4200 may proceed to diamond 4250, where measurements performed at block 4240 may be used to determine a desirable configuration for solar panels. In one implementation, either of two events may indicate such a desirable configuration for solar panels: existence of a relative maximum in the measurements and/or a relatively sudden trend of decreasing values of measurements. For example, a determination may be made as to whether a relatively high value (e.g., a maximum value) of the measurements exists or if relatively low values of the measurements prevail beyond a particular configuration change. For example, such a relatively high value may correspond to a desirable configuration of solar panels, such as at a particular fold angle, for example. Such a relatively high value may be detected by any of a number of techniques. For example, a sudden drop in measurement values after a trend of increasing measurement values may indicate such a relatively high value. On the other hand, a relatively sudden drop in measurement values beyond a particular measurement may also correspond to a desirable configuration of solar panels. For example, increasing a fold angle beyond the relatively sudden drop in measurement values may yield increasing additional area 4005, but light gathering or electrical power-generating performance may suffer by further decreasing fold angles.

If no such relatively high value is detected, then process 4200 may proceed to block 4260, where the solar panels may continue to be changed (e.g., folded at ever-increasing angles). Process 4200 may further return to block 4240, where light gathering or electrical power-generating performance may be measured again. On the other hand, if a relatively high value is detected at diamond 4250, then process 4200 may proceed to block 4270, where the solar panels may be held at a configuration corresponding to the relatively high value. At oval 4280, process may return to block 4210 to repeat and to further monitor for desirable solar panel configuration with respect to sky conditions.

For an illustrative example, in sunny skies, foldable solar panel 3700 may comprise a flattened configuration as shown in FIG. 38, for example. The weather becomes cloudy, and sunny skies are replaced with gray skies. A decrease in generated solar power or light collection may indicate such gray sky conditions. (In one implementation, generated solar power or light collection may be monitored as a function of time of day, day of month, and so on. Thus, a processor, for example, may determine whether a decrease in generated solar power or light collection may be due to time or day or increasing clouds) Foldable solar panel 3700 may then be folded to comprise a folded configuration as shown in FIG. 37, for example. However, measurements of generated solar power or light collection may be performed while folding solar panel 3700. As an example, such measurements may be performed every 10.0 degrees of fold angle 3705. Table 1 shows data regarding the present example.

TABLE 1

| | | | Measured | |
|---|---|---|---|---|
| | | | generated power | Fold angle |
| Case | Sky condition | Time of day | (kilowatts—kW) | (degrees) |
| A | Sunny skies | 10:30AM | 2.3 | Flat - 180 |
| B | Sunny skies | 1:30PM | 3.1 | Flat - 180 |
| C | Gray skies | 1:33PM | 2.4 | Flat - 180 |
| D | Gray skies | 1:33PM | 2.45 | 170 |
| E | Gray skies | 1:33PM | 2.47 | 160 |
| F | Gray skies | 1:34PM | 2.43 | 80 |
| G | Gray skies | 1:34PM | 2.1 | 70 |
| H | Gray skies | 1:34PM | 1.8 | 60 |

In case A, sunny skies prevail at 10:30 AM, and solar panels comprise a flat configuration. In case B, sunny skies prevail at 1:30 PM, solar panels comprise a flat configuration, and the sun is brighter than in the morning hours, so generated power may increase. In case C, clouds move in. A relatively sudden decrease (e.g., from 3.1 to 2.4 KW) in generated power may begin a process of changing configuration of the solar panels. In case D, a fold angle of the solar panels is 170.0 degrees, and generated power does not significantly change for such a change in fold angle. In case E, a fold angle of the solar panels is 160.0 degrees, and generated power does not significantly change for such a change in fold angle. Though Table 1 shows particular values and stages of a process, additional values and stages of the process may not be shown. In case F, a fold angle of the solar panels is 80.0 degrees. Generated power may be beginning to decrease. In case G, a fold angle of the solar panels is 70.0 degrees. Generated power decreases substantially compared to a last measurement value in case F. In case G, a fold angle of the solar panels is 60.0 degrees. Generated power further decreases substantially. Accordingly, it may be determined that a desirable fold angle is about 80.0 degrees. Thus, the solar panels may be held at a folded configuration defined, at least in part, by a fold angle of 80.0 degrees. If the weather changes, or measured generated power changes substantially, then such a fold angle may be adjusted again.

The following numerical example describes flattened or folded configurations of solar panels (e.g., flat or three-dimensional solar panels) in sunny and gray sky conditions. Case 1: If a solar panel in a flattened configuration 3910 is positioned to receive direct sunlight at a normal incidence (e.g., perpendicular to the panel surface), 100.0 watts of electricity may be generated, for example. If the solar panel in the flattened configuration comprises an area of 5.0 square meters, then electrical power may be generated at an “efficiency” of 100.0/5.0=20.0 watts per square meter. Case 2: Cloudy skies replace sunny skies of Case 1. Such cloudy skies result in a 40% drop in electrical power generation ability. Accordingly, if the solar panel of Case 1 receives scattered light on a cloudy day, 60.0 watts of electricity may be generated, for example. Thus, electrical power may be generated at an “efficiency” of 60.0/5.0=12.0 watts per square meter. Case 3: Solar panel in a flattened configuration 3910 is replaced with folded configuration 3900 during cloudy skies of Case 2. Thus, for example, surface area to receive scattered light may be increased by 30% so that 30% more power may be generated. Thus, electrical power may be generated at an “efficiency” of 12.0+0.30*12.0=16 watts per square meter.

In a particular implementation, a method of operating a three-dimensional solar panel configuration may comprise: measuring first electrical power produced by a first solar panel facing a first direction; measuring second electrical power produced by a second solar panel facing a second direction different from that of the first direction; and comparing the first electrical power to the second electrical power. If such a comparison yields a substantial difference, then the method may include positioning the first and/or the second solar panels to face directions that are substantially the same as one another.

In terms of describing such a method using normal vectors, the method may comprise: measuring a first electrical signal produced by a first solar panel having a first normal vector; measuring a second electrical signal produced by a second solar panel having a second normal vector different from that of the first normal vector; and comparing the first electrical signal to the second electrical signal. If such a comparison yields a substantial difference, then the method may further include positioning the first and/or the second solar panels so that their respective normal vectors are substantially the same as one another. If such a comparison does not yield a substantial difference, then the method may include positioning the first and/or the second solar panels in order to achieve a desired (e.g., optimal, maximum, etc.) generated solar power from the panels. Herein, the term “normal to a surface” refers to a direction perpendicular to a surface, and a normal vector describes a direction of a surface.

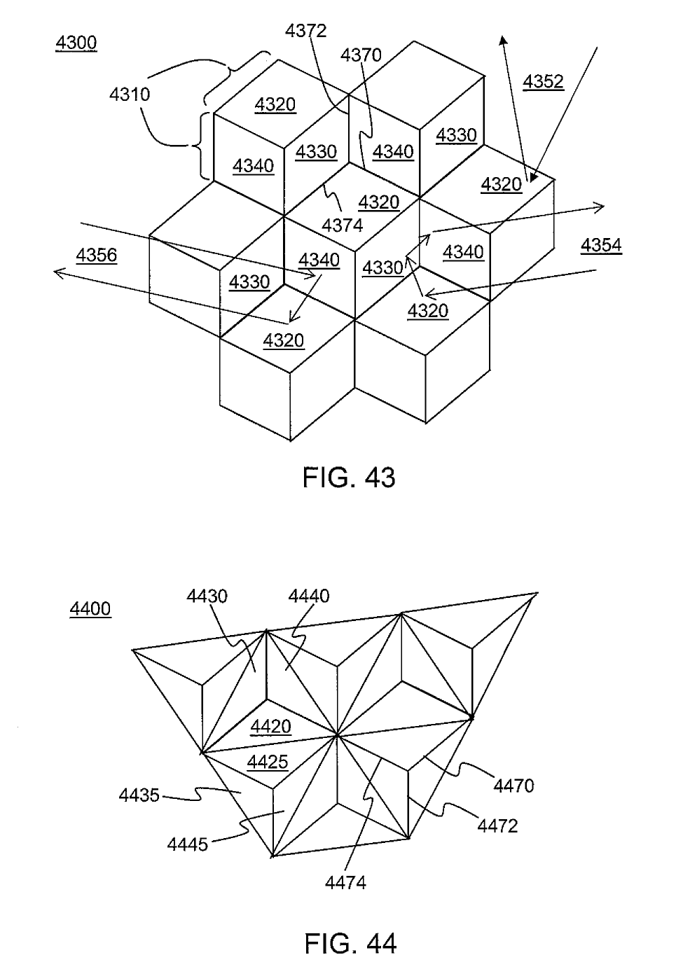

FIG. 43 is a perspective view showing a three-dimensional solar panel 4300, according to another embodiment. Although it is desirable for a solar panel or PV cell to absorb all of the light that it receives, physical properties of surfaces of solar panels or PV cells (e.g., plastic, glass, or other such transparent materials) may lead to a portion of received light being reflected away. Such reflection may result in reduced efficiency of solar power generation of the solar panel or PV cell. Anti-reflection coatings may be applied to surfaces to reduce reflection, but such coatings may not eliminate reflection.

Three-dimensional solar panel 4300 may provide a benefit in that light reflected from a first PV cell of the solar panel may be received by a second PV cell, which may utilize the reflected light to generate solar power. Further, light reflected from the second PV cell of the solar panel may be received by a third PV cell, which may again utilize the reflected light to generate solar power. Utilizing such reflected light one or more times may be accomplished by a particular arrangement of solar panel portions or PV cell portions 4320, 4330, and 4340, for example. In an implementation, solar panel 4300 need not involve a lens or receive light via a lens or other collimating device, though claimed subject matter is not so limited. Three-dimensional solar panel 4300 may comprise one or more sets of such solar panel portions or PV cell portions, which are herein called corner panels. Accordingly, solar panel 4300 may comprise one or more corner panels arranged adjacent to one another. A corner panel may comprise surfaces 4320, 4330, and 4340 that include PV cells. In an implementation, surfaces 4320, 4330, and 4340 may be substantially perpendicular to one another and intersect at their edges. For example, edges 4370, 4372, and 4374 (and thus surfaces 4320, 4330, and 4340) may be mutually perpendicular to one another. In another implementation, surfaces 4320, 4330, and 4340 may be substantially flat or rigid. Such an arrangement, as discussed above, may provide an opportunity for a single beam of incoming light to impinge on up to three PV cells respectively located on surfaces 4320, 4330, and 4340 of a corner panel.

For example, light 4356 may be received by surface 4340 and a portion of light 4356 may then be reflected and subsequently received by surface 4320. Thus, both surfaces 4340 and 4320 may be used to generate electricity by receiving a single light beam 4356. In another example, light 4354 may be received by surface 4320 and a portion of light 4354 may then be reflected and subsequently received by surface 4330. Further, a portion of light 4354 may then be reflected and subsequently received by surface 4340. Thus, three surfaces 4320, 4330, and 4340 may be used to generate electricity by receiving a single light beam 4354. In yet another example, light 4352 may be received by surface 4320 and a portion of light 4352 may then be reflected. In such a case as shown in FIG. 43, a direction of incident light 4352 may be such that the reflected light may not impinge on another surface. Such a case may not be desirable, but in a relatively small portion of light incident upon solar panel 4300 may behave similar to that of light 4352. For example, during cloudy sky conditions, sunlight may be scattered so that solar panel 4300 may receive such light from various directions. Solar panel 4300 may provide a benefit in that a relatively large portion of scattered light received by solar panel 4300 may be received by two or three surfaces 4320, 4330, or 4340, so that at least a portion of light reflected from a first and/or second surface may be utilized to generate solar power.

In one implementation, solar panel 4300 may comprise substantially cubic structures 4310 that include surfaces 4320, 4330, and/or 4340. For example, an array or other arrangement of such cubic structures may comprise solar panel 4300. At least a portion of surfaces 4320, 4330, or 4340 may include one or more PV cells. As an illustrative example, borrowing terminology from crystallography, substantially cubic structures 4310 may comprise unit cells that may form solar panel 4300. Though solar panel 4300 is shown in FIG. 43 to have seven such unit cells, solar panel 4300 may comprise any number of unit cells, and may include partial unit cells, for example. Thus, FIG. 43 is merely intended to show a representative portion of solar panel 4300 according to a particular implementation. In a particular implementation, surfaces 4320, 4330, or 4340 may have areas ranging from that of the microscopic level or an order of square millimeters to square meters, though claimed subject matter is not so limited. Solar panel 4300 may be positioned at any angle relative to gravity or the sun. As an example, one value of angle may be more desirable than another value of angle in that light, whether substantially scattered or substantially direct, may reach a relatively large portion of surfaces 4320, 4330, or 4340 depending, at least in part, on such an angle. Of course, such details, terminology, and sizes are merely examples, and claimed subject matter is not so limited.

FIG. 44 is a perspective view showing a three-dimensional solar panel 4400, according to yet another embodiment. Solar panel 4400 may be similar to that of solar panel 4300 except that surfaces 4420, 4430, or 4440 may be substantially triangular shape. Three-dimensional solar panel 4400 may comprise one or more sets of solar panel portions or PV cell portions, which are herein called corner panels. Accordingly, solar panel 4400 may comprise one or more corner panels arranged adjacent to one another. A corner panel may comprise surfaces 4420, 4430, and/or 4440 that include PV cells. In an implementation, surfaces 4420, 4430, and 4440 may be substantially perpendicular to one another and intersect at their edges. For example, edges 4470, 4472, and 4474 (and thus surfaces 4420, 4430, and 4440) may be mutually perpendicular to one another. In addition, a corner panel may also comprise surfaces 4425, 4435, and/or 4445 that include PV cells. Similarly, surfaces 4425, 4435, and 4445 may be substantially perpendicular to one another and intersect at their edges. To describe a relation between corner panels that comprise surfaces 4420, 4430, and 4440 and corner panels that comprise surfaces 4425, 4435, and 4445, for example, surfaces 4420 and 4425 may be perpendicular to each other. As an illustrative example, borrowing terminology from crystallography, solar panel 4400 may comprise two types of unit cells, wherein one type of unit cell includes surfaces 4420, 4430, and 4440 and the other type of unit cell includes surfaces 4425, 4435, and 4445. Though solar panel 4400 is shown in FIG. 44 to have three of the one type of unit cells and five of the other type of unit cells, solar panel 4400 may comprise any number or combination of unit cells, and may include partial unit cells, for example. Thus, FIG. 44 is merely intended to show a representative portion of solar panel 4400 according to a particular implementation.

In an implementation, surfaces 4420, 4430, 4440, 4425, 4435, and 4445 may be substantially flat or rigid. Such an arrangement, as discussed above, may provide an opportunity for a single beam of incoming light to impinge on up to three PV cells respectively located on surfaces 4420, 4430, 4440, 4425, 4435, and 4445 of a corner panel. In a particular implementation, surfaces 4420, 4430, 4440, 4425, 4435, and 4445 may have areas ranging from that of the microscopic level or an order of square millimeters to square meters, though claimed subject matter is not so limited. Solar panel 4400 may be positioned at any angle relative to gravity or the sun. As an example, one value of angle may be more desirable than another value of angle in that light, whether substantially scattered or substantially direct, may reach a relatively large portion of surfaces 4420, 4430, 4440, 4425, 4435, or 4445 depending, at least in part, on such an angle. In an implementation, solar panel 4400 need not involve a lens or receive light via a lens or other collimating device. Of course, such details, terminology, and sizes are merely examples, and claimed subject matter is not so limited.

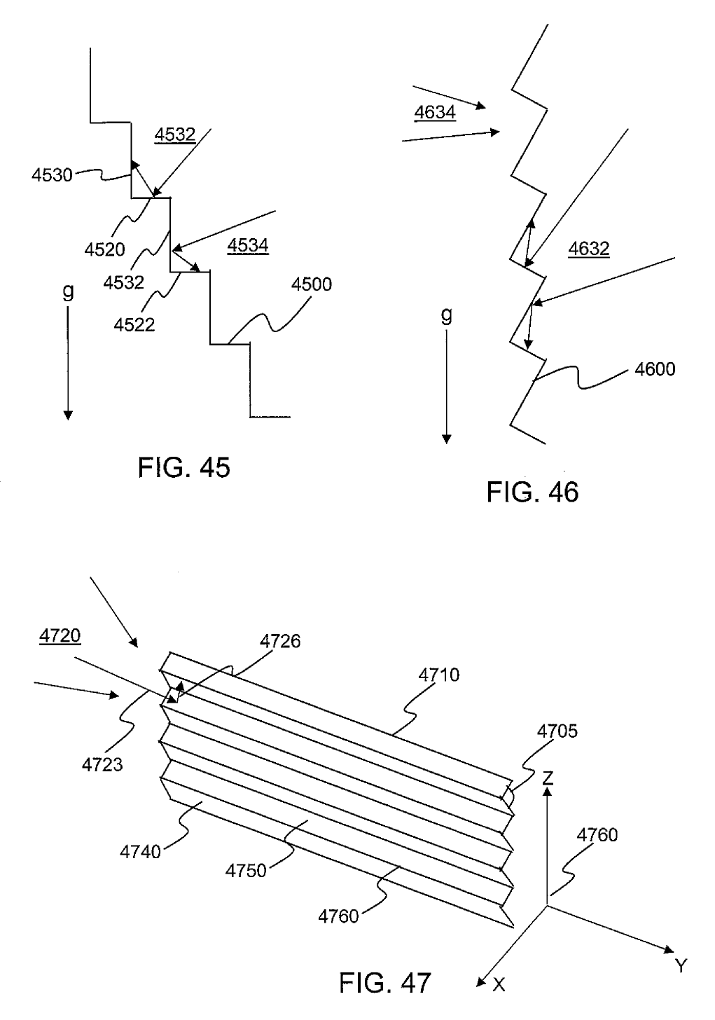

FIGS. 45 and 46 are side views showing a three-dimensional solar panel, according to embodiments. For example, solar panels 4500 or 4600 may be similar to solar panel 4300 or 4400. Accordingly, a single beam of light may be received by PV cells on more than one surface, as explained above. In other words, light reflected from a first surface (e.g., comprising one or more PV cells) may be collected or received by a second surface (which may also include one or more PV cells). For example, light 4532, which may comprise substantially scattered or substantially direct sunlight, may impinge on surface 4520, which may reflect a portion (albeit small, for example) of light 4532. Subsequently, surface 4530 may receive such reflected light. In another example, light 4534 may impinge on surface 4532, which may reflect a portion of light 4534. Subsequently, surface 4522 may receive such reflected light. In an implementation, solar panel 4500 may provide a benefit in that multiple surfaces of panel 4500, which may include PV cells, may receive incident light or reflected light from various directions, such as scattered light. For example, light 4532 and light 4534 may arrive at solar panel 4500 at substantially different angles, yet both light 4532 and light 4534 and reflected light thereof may be received by two or more surfaces of solar panel 4500. (A third surface may receive secondary reflected light, as described above and shown in FIG. 43. For example, light 4354 may be reflected twice. However, third surfaces, though present, are not drawn in FIGS. 45 and 46, for sake of clarity).

In an implementation, both sides of surfaces of solar panels 4500 or 4600 (and thus solar panels 4300 or 4400) may include PV cells. For example, solar panel 4600 may use PV cells to generate electricity by receiving light 4634 and/or light 4632 on one or both sides of solar panel 4600.

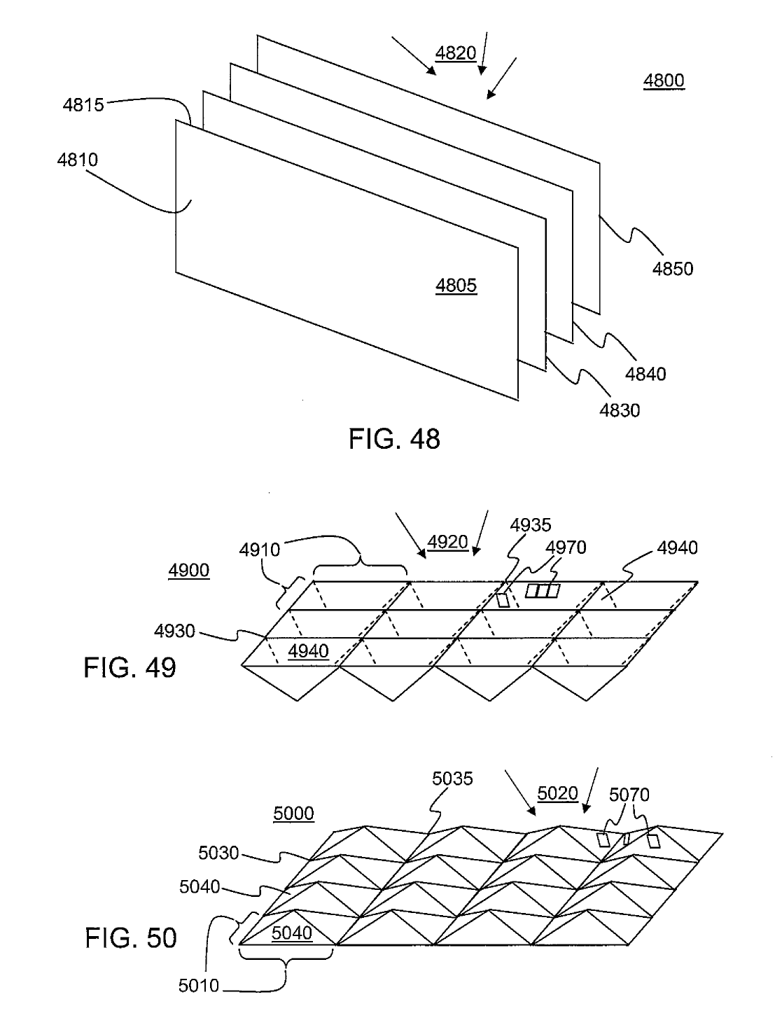

Solar panel 4600 may be similar to solar panel 4500 except that orientation of one may be different form that of the other. Such orientation may be relative to gravity g and/or sun direction, for example. Solar panels 4300, 4400, 4500, or 4500 may provide a benefit in that orientation of such solar panels need not be critical to successful operation in relatively efficiently collecting light. Also, surfaces of such solar panels may geometrically operate to receive light from various directions, such as may be the case for scattered light. In one implementation, solar panel 4600, which may have a steeper angle with respect to gravity, may be more conducive to collecting light on both sides of its surfaces compared to that of solar panel 4500. In a particular implementation, solar panel 4600, having a relatively vertical inclination, may be mounted on a wall of a building or mounted vertically (e.g., in a field or on a rooftop). For example, as discussed in detail below and shown in FIG. 48, multiple solar panels 4600 (or 4300, 4400, or 4500) may be placed in a substantially vertical orientation.

In a particular implementation, a solar panel, such as that shown in FIGS. 45 and 46 for example, may comprise a first set of two or more surfaces comprising PV cells, wherein the surfaces of the first set may comprise substantially normal vectors that are parallel to one another. For example, surfaces 4530 and 4532 may comprise such a first set of surfaces. The solar panel may also comprise a second set of two or more surfaces comprising PV cells, wherein the surfaces of the second set may comprise substantially normal vectors that are parallel to one another. For example, surfaces 4520 and 4522 may comprise such a second set of surfaces. The normal vectors of the first set may be substantially perpendicular to the normal vectors of the second set. Also, the surfaces of the first set may be disposed in positions that alternate with the surfaces of the second set. For example, a first set surface is disposed between two second set surfaces, and vise versa.

FIG. 47 is a perspective view showing a three-dimensional solar panel 4710, according to still another embodiment. Surfaces of the solar panel may comprise PV cells to generate electricity in response to receiving light. In one implementation, side views of solar panel 4710 may be similar to that shown in FIG. 45 or 46. Accordingly, solar panel 4710 may provide a benefit in that light reflected from a first PV cell may be collected or received by a second cell. For example, scattered light 4720 may comprise a light beam 4723 in which a portion 4726 may be reflected from a first incident surface and received by a second surface of solar panel 4710.

Because solar panel 4710 may be relatively efficient at receiving scattered light from a variety of direction, such a solar panel may be oriented substantially vertically along a Z-axis of a coordinate system 4760 shown in the figure. Thus, solar panel 4710 may be mounted on walls, sides of buildings, and so on.

In one implementation, solar panel 4710 may comprise a foldable three-dimensional solar panel similar to solar panel 3700 shown in FIG. 37, for example. In such a case, solar panel 4710 may provide benefits related to manufacturing, shipping, stocking, retailing, installing, and so on. For example, solar panel 4710 may be shipped, packaged, or sold in a folded configuration, which may be relatively convenient and compact. An installer (such as a home owner or professional) may mount a bottom or top edge of folded solar panel 4710 to a portion of a wall and then stretch, extend, or unfold solar panel 4710 to cover a large portion of the wall. An extent of such stretching, extending, or unfolding may determine a particular size of solar panel 4710. For example, solar panel 4710 may be stretched (e.g., to a flattened configuration) to a length of nine feet, but a wall to which solar panel 4710 is to be mounted may only be eight feet tall. Accordingly, solar panel 4710 need not be extended beyond eight feet to its full potential length (e.g., nine feet).

As mentioned above, solar panel 4710 may be folded, unfolded, stretched, compressed, and so on, in an accordion fashion, for example. Solar panel 4710 may comprise one or more individual solar panels 4740 and 4750. Geometrical positioning of surfaces of individual solar panels 4740 and 4750 of solar panel 4700 may geometrically hinder direct sunlight from reaching these surfaces. However, scattered light 4720 need not be so hindered since such light may arrive from substantially all skyward directions, whereas non-scattered light may come from one direction, the sun, for example. Cloudy skies may produce such scattered sunlight.

In one embodiment, an angle 4705 between solar panels 4740 and 4750 may be determined to optimize solar gain. For example, if angle 4705 is too small (e.g., sharp folding), then solar panel 4710 may occupy a desirably small wall area but solar radiation may reach relatively few portions of solar panel 4710. On the other hand, if angle 4705 is too large (e.g., an almost flattened configuration), solar radiation may reach all portions of solar panel 4710 but occupied wall area may be undesirably large. Also, a benefit of utilizing light reflected from PV cells, as described above, may be reduced.

In an implementation, individual solar panels 4740 and 4750 may be connected by hinging or flexible material along seams 4760. Individual solar panels 4740 and 4750 may be coupled to one another electrically and/or mechanically, or such panels may be configured so that their respective electrical connections are separate. In a particular embodiment, one or more of individual solar panels 4740 and 4750 may be connected to one another along their respective edges. In another particular embodiment, individual solar panels 4740 and 4750 may be interconnected but spaced apart to form a relatively small gap along seams 4760. In an embodiment, individual solar panels 3740 and/or 3750 may comprise a single, or one or more solar panels or PV cells. In one particular embodiment, solar panel 4710 may comprise portion 4740 and portion 4750 that are substantially rigid with respect to one another.

FIG. 48 is a perspective view of a solar panel bank 4800, comprising a plurality of solar panels, according to an embodiment. For example, to take advantage of the fact that scattered light may be received from various directions at once, packing density of solar panels or PV cells may be relatively high by arranging a plurality of such solar panels or PV cells in a substantially vertical configuration. As discussed above, increasing solar gain (e.g., the amount of light collected to generate electricity) may be accomplished by increasing surface area of solar panels while maintaining a relatively small footprint (e.g., area of land, rooftop, or wall). Such a process of increasing solar gain for a given occupied area may be referred to as packing efficiency of PV cells, for example. Solar panels having a third dimension, such as a depth, in addition to width and length, for example (e.g., pyramidal shapes compared to squares or triangles) may provide a relatively high packing density. To increase packing efficiency further, multiple arrays of such three-dimensional solar panels may be arranged as shown in FIG. 48.

In one implementation, solar panel unit 4805 may comprise an array of solar panels adapted to receive scattered light 4820. First side 4810, second side 4815, or both may include such solar panels. In one example, solar panel unit 4805 may comprise an array of pyramidal solar panels, such as that shown in FIG. 49 or 50. In another implementation, additional solar panel units 4830, 4840, or 4850 may be positioned adjacent to solar panel units 4805 to further increase the number of deployed solar panels or PV cells. For an illustrative example, a solar panel unit may have a height of eight feet and a length of sixteen feet and include an array of thirty-two three-dimensional solar panels having base dimensions of a two foot square. In addition, as mentioned above, first side 4810, second side 4815, or both sides may include such a plurality of solar panels. A plurality of such solar panel units may be spaced from one another by four feet. Of course, such particular numbers or values are merely examples, and claimed subject matter is not so limited.

In one implementation, solar panel unit 4805 may comprise a plurality of pyramidal-shaped solar panels, such as those shown in FIG. 49 or 50, as mentioned above. In another implementation, solar panel unit 4805 may comprise a plurality of solar panels 4300, 4400, or 4710, shown in FIGS. 43-47. Though solar panel units are shown oriented in a vertical fashion, claimed subject matter is not limited in this respect.

FIG. 49 is a perspective view showing multiple pyramidal three-dimensional solar panels arranged in arrays, according to an embodiment. In particular, an array 4900 of pyramidal three-dimensional solar panels 4910 may comprise inside surfaces 4940 including PV cells 4970, for example. Array 4900 may be similar to array 750 shown in FIG. 7, for example. Solar panels 4910 may comprise a rigid material covered with PV cells 4970 (a few of which are shown in the figure), for example. In one implementation, edges 4930 or 4935, where solar panels 4910 may join one another, may be flexible or pliable to allow array 4900 to comply with non-planar substrates or mounting surfaces, such as a mounting surface for solar panel unit 4805 shown in FIG. 48, for example. For a particular example, solar panels 4910 may have dimensions in the order of millimeters to meters.

FIG. 50 is a perspective view showing multiple pyramidal three-dimensional solar panels arranged in arrays, according to an embodiment. In particular, an array 5000 of pyramidal three-dimensional solar panels 5010 may comprise outside surfaces 5040 including PV cells 5070 (a few of which are shown in the figure), for example. Array 500 may be similar to array 4900 in an inverted configuration. Solar panels 5010 may comprise a rigid material covered with PV cells 5070, for example. In one implementation, edges or valleys 5030 or 5035, where solar panels 5010 may join one another, may be flexible or pliable to allow array 5000 to comply with non-planar substrates or mounting surfaces, such as a mounting surface for solar panel unit 4805 shown in FIG. 48, for example. For a particular example, solar panels 5010 may have dimensions in the order of millimeters to meters.

While there has been illustrated and described what are presently considered to be example embodiments, it will be understood by those skilled in the art that various other modifications may be made, and equivalents may be substituted, without departing from claimed subject matter. Additionally, many modifications may be made to adapt a particular situation to the teachings of claimed subject matter without departing from the central concept described herein. Therefore, it is intended that claimed subject matter not be limited to the particular embodiments disclosed, but that such claimed subject matter may also include all embodiments falling within the scope of the appended claims, and equivalents thereof.

What is claimed is:

1. A three-dimensional solar panel to mount to a surface, said solar panel comprising:
a substrate to physically support photovoltaic cells, said substrate having a shape that includes a hollow region; and
a base to contact said surface, wherein upon said contact, said hollow region is enclosed by said substrate and said surface.

2. The solar panel of claim 1, wherein said hollow region is at least partially filled with insulation material.

3. The solar panel of claim 1, wherein said substrate comprises insulation material.

4. The solar panel of claim 1, wherein said substrate comprises a conical or pyramidal shape;

5. An apparatus comprising:
a solar panel to rotate by at least a complete revolution about an axis while collecting light to generate electrical energy.

6. The apparatus of claim 5, wherein said solar panel comprises a three-dimensional solar panel including individual solar panel portions that simultaneously face two or more different portions of sky.

7. The apparatus of claim 5, wherein said axis is through said solar panel.

8. The apparatus of claim 7, wherein said solar panel comprises a substantially pyramidal shaped solar panel.

9. The apparatus of claim 5, wherein said solar panel is mounted on a rotating portion of a wind gauge.

10. The apparatus of claim 5, further comprising:
electronic circuitry to determine weather conditions based, at least in part, on characteristics of said generated electrical energy.

11. The apparatus of claim 10, wherein said characteristics of said generated electrical energy comprise modulation intensity.

12. The apparatus of claim 5, further comprising a sail to convert air, gas, or liquid flow to a torque to rotate said solar panel.

13. The apparatus of claim 5, further comprising a motor to apply a torque to rotate said solar panel.

14. A solar panel comprising:
first, second, and third substantially planer surfaces that include one or more photovoltaic (PV) cells, wherein said first, second, and third surfaces are arranged to be mutually perpendicular to one another so that a particular beam of light impinging on said first surface partially reflects to impinge on said second surface and partially reflects to impinge on said third surface.

15. The solar panel of claim 14, wherein another particular beam of light impinging on said first surface partially reflects to impinge on said second surface without impinging on said third surface.

16. The solar panel of claim 14, wherein another particular beam of light impinging on said first surface partially reflects without impinging on said second surface and without impinging on said third surface.

17. The solar panel of claim 14, wherein said first, second, and third substantially planer surfaces collectively comprise a corner cube.

18. The solar panel of claim 14, further comprising:
a plurality of said first, second, and third substantially planer surfaces arranged in an array.

19. The solar panel of claim 18, wherein said array is oriented substantially parallel with gravity.

20. The solar panel of claim 19, further comprising:
a plurality of said arrays arranged substantially parallel with one another.
